(19) United States
(12) Patent Application Publication
(10) Pub. No.: US 2005/0190225 A1
(43) Pub. Date: Sep. 1, 2005

(54) Liquid droplet ejection apparatus, method of manufacturing electro-optical device, electro-optical device, and electronic apparatus

(76) Inventor: Kenji Sakamoto, Suwa-shi (JP)

Correspondence Address: HARNESS, DICKEY & PIERCE, P.L.C., P.O. BOX 828, BLOOMFIELD HILLS, MI, 48303, US

(21) Appl. No.: 11/055,379

(22) Filed: Feb. 10, 2005

(30) Foreign Application Priority Data
Feb. 13, 2004 (JP) 2004-036760
Oct. 13, 2004 (JP) 2004-299439

(51) Int. Cl. B41J 2/165

(52) U.S. Cl. 347/22

(57) ABSTRACT

A function liquid droplet ejection apparatus includes an imaging apparatus for performing imaging on a workpiece with a function liquid droplet ejection head and a maintenance apparatus for performing maintenance of the function liquid droplet ejection head. The imaging apparatus includes: an X-axis table having the workpiece mounted thereon and moving the workpiece in the X-axis direction; a plurality of carriage units having the function liquid droplet ejection head mounted on a carriage; and a Y-axis table moving the plurality of, carriage units between an imaging area and a maintenance area. The Y-axis table is capable of moving the plurality of carriage units independently.

### RELATED APPLICATIONS

This application claims priority to Japanese Patent Application Nos. 2004-036760 filed Feb. 13, 2004 and 2004-299439 filed Oct. 13, 2004 which are hereby expressly incorporated by reference herein in their entirety.

### BACKGROUND OF THE INVENTION

1. Field of the Invention

This invention relates to a liquid droplet ejection apparatus which ejects (or discharges) function (or functional) liquid onto a workpiece so as to perform imaging (or drawing) on the workpiece while moving function liquid droplet ejection heads relative to the workpiece and also performing maintenance of the function liquid droplet ejection heads, a method of manufacturing an electro-optical device, an electro-optical device, and an electronic apparatus.

2. Description of the Related Art

A known liquid droplet ejection apparatus is of an inkjet type used for manufacturing an organic electro-luminescent (EL) device or a color filter. The function liquid droplet ejection apparatus includes, on a stone surface plate, an imaging apparatus including an X-axis table having a substrate mounted thereon, serving as a workpiece, and a Y-axis table having function liquid droplet ejeciton heads mounted thereon, in addition to having a maintennce apparatus thereon, juxtaposed to the imaging apparatus, sucking function liquid from the function liquid droplet ejection heads and wiping the same. The Y-axis table has: a main carriage movably suspended therefrom. The main carriage (carriage) has a sub-carriage (a head plate), and a head unit made up of twelve function liqud droplet ejection heads mounted on the sub-carriage, supported thereby.

Thus, the substrate is reciprocated by the X-axis table in the main scanning direction (in the X-axis direction), function liquid is ejected from each function liquid droplet ejection head in a manner synchronized with this reciprocal movement, and the head unit (including the function liquid droplet ejection heads) is moved with respect to each reciprocation by the Y-axis table in the sub-scanning direction (in the Y-axis direction), whereby imaging is performed across the entire area of the substrate.

When maintenance of the function liquid droplet ejection heads is performed, the head unit is sent to the maintennce apparatus by the Y-axis table and, in this state, the head unit is sucked by a suction unit so as to eliminate its function liquid and is wiped by a wiping unit. When the head unit detachably supported by the main carriage is replaced with new one, the head unit is moved to a home position opposite to the maintennce apparatus so as to be replaced.

With such a known liquid droplet ejection apparatus, since it is needed to eject function liquid while moving the head unit in the X-axis and Y-axis directions relative to a substrate (a workpiece), the large-sized workpiece causes a longer time (tact time) for being processed. In such a case, in a similar manner to a so-called line printer, a head unit having a structure in which a single imaging line is covered by all function liquid droplet ejection heads can be imagined.

With such a structure, however, when a part of the function liquid droplet ejection heads has a problem, the overall head unit must be replaced with a new one, thereby leading to a complicated replacing operation. Also, the suction unit and the wiping unit must be constructed so as to correspond to the large head unit, thereby leading to a large-sized maintennce apparatus.

### SUMMARY OF THE INVENTION

Accordingly, it is an object of this invention to provide a liquid droplet ejection apparatus in which a large-sized head unit can be provided without impairing replaceability and maintenability of the apparatus, a method of manufacturing an electro-optical device, an electro-optical device, and an electronic apparatus.

According to one aspect of this invention, there is provided a liquid droplet ejection apparatus comprising: imaging means for performing imaging on a workpiece facing an imaging area by ejecting function liquid onto the workpiece while moving a function liquid droplet ejection head having function liquid introduced therein relative to the workpiece; and maintenance means juxtaposed to the imaging means, for performing maintenance of the function liquid droplet ejection head facing the maintenance area. The imaging means comprises: an an X-axis table for mounting thereon the workpiece and for moving the workpiece in the X-axis direction which serves as a main scanning direction; a plurality of carriage units each having mounted on a carriage the function liquid droplet ejection head; and a Y-axis table for moving the plurality of carriage units between the imaging area and the maintenance area. The Y-axis table is capable of moving the plurality of carriage units independently.

With this structure, an imaging line is formed by the plurality of carriage units each having mounted on a carriage the function liquid droplet ejection head and the plurality of carriage units can be independently moved by the Y-axis table. Therefore, a wide (long) imaging line can be formed by arranging the plurality of carriage units, and also the carriage units can be arranged so as to independently face the maintenance means for performing maintenance work. Also, the Y-axis table allows the carriage units to be moved independently to a replacement area. The function liquid droplet ejection heads can thus be replaced with new ones for respectve carriage units. Accordingly, a large-size head unit for forming a wide (long) imaging line can be constructed without impairing replaceability and maintenability.

In this case, preferably, a single imaging line corresponding to the width of the imaging area is made up of all discharge nozzles of a plurality of the function liquid droplet ejection heads mounted on the plurality of carriage units.

With this structure, imaging can be performed on a single workpiece without the sub-scanning (intermittent movement in the Y-axis direction), whereby a tact time for performing imaging on the workpiece can be drastically reduced.

In this case, preferably, a drive source of the Y-axis table is made up of a linear motor.

With this structure, the plurality of carriage units can be independently and also accurately moved.

In this case, preferably, each of the carriage units comprises: a carriage supported by a slider of the Y-axis table; and a head unit which is detachably held by the carriage and which has the function liquid droplet ejection head and a head plate having mounted thereon the function liquid droplet ejection head. The maintenance area serves also as an exchange area for attaching or detaching each head unit to or from the corresponding carriage.

With this structure, the maintenance area allows the head unit to be easily attached to or detached from its carriage. Namely, the function liquid droplet ejection head can be easily replaced with a new one through the corresponding head unit. This structure is especially useful when there are used the function liquid droplet ejection head which is often replaced with a new one due to properties of function liquid.

In this case, preferably, each of the head plates has a plurality of the function liquid droplet ejection heads mounted thereon. The plurality of the function liquid droplet ejection heads are disposed in a predetermined arrangement pattern such that all discharge nozzles thereof make up a partial imaging line so as to serve as a part of the imaging line, and the arrangement pattern is achieved by a group of the liquid droplet ejection heads displaced in a stepwise manner and also in a single row in the X-axis and Y-axis directions, respectively.

Similarly, preferably, each of the head plates has the plurality of the function liquid droplet ejection heads mounted thereon. The plurality of the function liquid droplet ejection heads are disposed in a predetermined arrangement pattern such that all discharge nozzles thereof make up a partial imaging line so as to serve as a part of the imaging line, and the arrangement pattern is achieved by a group of the liquid droplet ejection heads displaced in a stepwise manner, respectively in the X-axis and Y-axis directions and also in a plurality of rows in the Y-axis direction.

With this structure, an imaging line can be formed by a large number of the function liquid droplet ejection heads, each having a standard number of discharge nozzles, and also the head unit can be revitalized by disposing of only malfunctioned ones of the function liquid droplet ejection heads, whereby the yield rate of the function liquid droplet ejection heads is not undermined. Also, with the latter arrangement pattern, the entire width of the plurality of carriage units in the X-axis direction can be reduced without changing the entire length of the plurality of carriage units in the Y-axis direction, thereby leading to a compact structure of the overall apparatus.

In this case, each of the carriage units has a function liquid tank mounted thereon for feeding function liquid to the function liquid droplet ejection head.

With this structure, the length between the function liquid tank and the corresponding function liquid droplet ejection head can be drastically reduced, and also, the layout of function liquid tubes between the function liquid tanks and the corresponding function liquid droplet ejection head can be drastically simplified. Thus, the function liquid droplet ejection head can stably eject function liquid. Meanwhile, a pressure regulator is preferably interposed between the function liquid tank and the function liquid droplet ejection head. This structure eliminates a problem of unstable discharge of function liquid due to fluctuation in water head between the function liquid tank and the function liquid droplet ejection head.

In this case, the maintenance means comprises a suction unit for sucking function liquid from each of the ejection nozzles of the function liquid droplet ejection head, and a wiping unit for wiping the nozzle surface of the sucked function liquid droplet ejection head with a wiping sheet.

With this structure, when the function liquid droplet ejection heads are sucked with the suction unit and wiped with the wiping unit, the ejection functions of the function liquid droplet ejection head of each carriage unit can be satisfactorily maintained. When the suction unit and the wiping unit are constructed so as to correspond to a single carriage unit in order to perform maintenance (sucking and wiping processes) for each carriage unit, the maintenance mechanism is not needed to have a large size even when the entire size of the plurality of carriage units become large.

According to another aspect of this invention, there is provided a method of manufacturing an electro-optical device comprising forming a deposited film on the workpiece with function liquid droplets with the above-described function liquid droplet ejection apparatus.

According to still another aspect of this invention, there is provided an electro-optical device having formed a deposited film on the workpiece with function liquid droplets with the above-described function liquid droplet ejection apparatus.

With the above arrangement, the electro-optical device is manufactured with the function liquid droplet ejection apparatus which performs imaging on the workpiece very accurately and in a short time, thereby leading to manufacturing a reliable electro-optical device. Electro-optical devices (flat panel displays) include a color filter, a liquid crystal display device, an organic electro-luminescence (EL) device, a plasma display panel (PDP) device, an electron-emission device, and so forth. The electron-emission devices include a concept of so-called FED (field emission display) and SED (surface-conduction electron-emitter display). As the electro-optical device, there may be considered a device including forming metal wire line, a lens, a resist, a light-dispersing member, or the like.

According to yet another aspect of this invention, there is provided an electronic apparatus having mounted thereon an electro-optical device manufactured by the above-described method or having mounted thereon the above-described electro-optical device.

In this case, electronic apparatus includes a variety of electrical products aside from a cellular phone and a personal computer having a so-called flat panel display installed therein.

### BRIEF DESCRIPTION OF THE DRAWINGS

FIG. 1 is a schematic plan view of an imaging system according to an embodiment of this invention;

FIG. 2 is an external perspective view of a function liquid droplet ejection apparatus according to the embodiment;

FIG. 3 is a plan view of the function liquid droplet ejection apparatus according to the embodiment;

FIG. 4 is a front view of the function liquid droplet ejection apparatus according to the embodiment;

FIG. 5 is a side view of the function liquid droplet ejection apparatus according to the embodiment;

FIG. 6 illustrates a head unit, mainly focusing on a head plate of the head unit and its vicinity;

FIG. 7 is an external perspective view of a function liquid droplet ejection head;

FIG. 8 illustrates the head plate according to this embodiment, wherein FIG. 8A is an external perspective view of the head plate, and FIG. 8B is the head plate, viewed from its bottom;

FIG. 9 illustrates a modification of the head plate according to this embodiment, wherein FIG. 9A is an external perspective view of the modified head plate, and FIG. 9B is the modified head plate, viewed from its bottom;

FIG. 10 illustrates function liquid feeding means, wherein FIG. 10A illustrates function liquid feeding means and its vicinity, FIG. 10B is a sectional view of the function liquid feeding means;

FIG. 11 is an external perspective view of an angle frame and its vicinity;

FIG. 12 is a rear view of the angle frame and its vicinity;

FIG. 13 is an external perspective view of a divided suction unit and its vicinity;

FIG. 14 is a side view of the divided suction unit and its vicinity;

FIG. 15 is an external perspective view of a wiping unit and its vicinity;

FIG. 16 is a side view of the wiping unit and its vicinity;

FIG. 17 illustrates a transverse moving mechanism, wherein FIG. 17A illustrates the positional relationship between the function liquid droplet ejection head and a wiping sheet already used for wiping and yet to be driven by the transverse moving mechanism, and FIG. 17B illustrates the positional relationship between the function liquid droplet ejection head and the wiping sheet already used for wiping and also driven by the transverse moving mechanism;

FIG. 18 is a block diagram, showing a main control system of an imaging apparatus;

FIG. 19A to 19C illustrate the positional relationships between divided head units and the divided suction units during regular maintenance;

FIG. 20 is a modification of this embodiment during regular maintenance, wherein FIGS. 20A, 20B, and 20C illustrate the positional relationships during wiping operations of first, second, and sixth divided head units, respectively;

FIGS. 21A to 21C′ illustrate the positional relationships between the divided head units and the divided suction units during an exchanging operation of the heads;

FIG. 22 illustrates the positional relationships among the divided suction units during maintenance of a fifth divided head unit;

FIG. 23 is a flowchart showing a process of manufacturing a color filter;

FIGS. 24A to 24E are schematic sectional views of the color filter, showing it in order of its manufacturing steps;

FIG. 25 is a sectional view of an essential part of a first example liquid crystal device including the color filter according to this invention, showing the general structure of the first example liquid crystal device;

FIG. 26 is a sectional view of an essential part of a second example liquid crystal device including the color filter according to this invention, showing the general structure of the second example liquid crystal device;

FIG. 27 is a sectional view of an essential part of a third example liquid crystal device including the color filter according to this invention, showing the general structure of the third example liquid crystal device;

FIG. 28 is a sectional view of an essential part of a display device serving as an organic EL device;

FIG. 29 is a flowchart showing a manufacturing process of the display device serving as the organic EL device;

FIG. 30 is a schematic sectional view showing an essential part of an inorganic bank layer;

FIG. 31 is a schematic sectional view showing an essential part of an organic bank layer;

FIG. 32 is a schematic sectional view showing an essential part of a hole injection/transport layer;

FIG. 33 is a schematic sectional view showing a state in which the hole injection/transport layer is formed;

FIG. 34 is a schematic sectional view showing an essential part of a blue emitting layer;

FIG. 35 is a schematic sectional view showing an essential part of the blue emitting layer;

FIG. 36 is a schematic sectional view showing a state in which all color emitting layers are formed;

FIG. 37 is a schematic sectional view of an essential part of a cathode;

FIG. 38 is an exploded perspective view of an essential part of a display device serving as a plasma display panel (PDP) device;

FIG. 39 is a sectional view of an essential part of a display device serving as an electron-emission device (such as an FED device or an SED device); and

FIGS. 40A and 40B are respectively a plan view of an electron emission portion and its vicinity of the display device and a plan view showing a method of forming the electron emission portion.

### DESCRIPTION OF THE PREFERRED EMBODIMENTS

An imaging system according to an embodiment of this invention will be described with reference to the attached drawings. The imaging system according to this embodiment is incorporated into a production line of a so-called flat panel display such as a liquid crystal display device and forms coloring layers, which will be described later in detail, of a color filter for three colors of red (R), green (G), and blue (B).

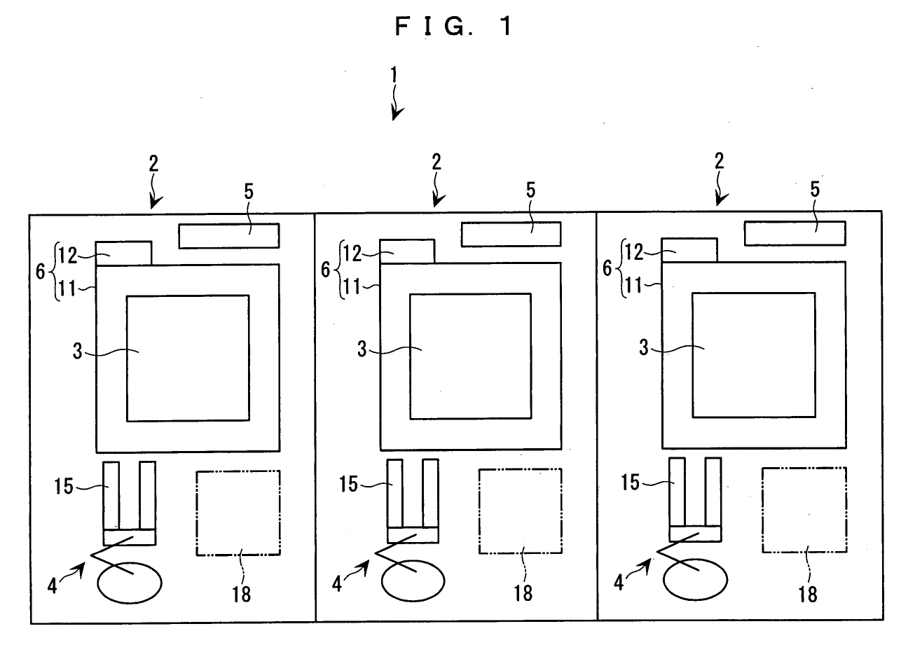

FIG. 1 is a schematic plan view of an imaging system 1. As shown in the figure, the imaging system 1 is made up of three sets of imaging units 2. Since the imaging units 2 correspond to the respective colors R, G, and B, when a workpiece W (a substrate) is sequentially introduced into the respective imaging units 2, a coloring layer for each color is formed on the workpiece W.

As shown in FIG. 1, each imaging unit 2 includes: a function liquid droplet ejection apparatus 3 for forming the coloring layer; a workpiece carrying-in/out apparatus 4 juxtaposed to the function liquid droplet ejection apparatus 3 and carrying in or carring out the workpiece W; and a control unit 5 connected to the corresponding apparatus and controlling the overall imaging unit 2. Also, as shown in the figure, the function liquid droplet ejection apparatus 3 is accommodated in a chamber apparatus 6. The chamber apparatus 6 is a so-called thermal chamber and accommodates the entire function liquid droplet ejection apparatus 3 under temperature control so as to perform liquid droplet ejection (imaging) on the workpiece W at certain temperature conditions. The chamber apparatus 6 includes a box-shaped chamber main body 11 having the overall function liquid droplet ejection apparatus 3 accommodated therein, and an air-conditioner 12 for controlling the temperature together with a control board (not illustrated) so as to keep the temperature inside the chamber main body 11 constant. Although not shown in the figure, the chamber main body 11 has an open/close door formed at the front part of the right side surface, serving as a workpiece carrying-in/out opening. For example, when the workpiece W is to be introduced into the function liquid droplet ejection apparatus 3, the workpiece W is accessible to the function liquid droplet ejection apparatus 3 accommodated in the chamber main body 11 through the open/close door.

The function liquid droplet ejection apparatus 3 includes function liquid droplet ejection heads 72 (not illustrated) and performs imaging on the workpiece W by introducing function liquid, in which a function material (filter material) corresponding to any one of red, green, and blue colors is dissolved into a function liquid solvent, into any one of the function liquid droplet ejection heads 72. The workpiece carrying-in/out apparatus 4 includes a robot arm 15 for transferring the workpiece W, and, with the robot arm 15, transports an unprocessed (yet to be drawn) workpiece W in the imaging unit 2 so as to introduce it in the function liquid droplet ejection apparatus 3, and also retrieves the processed (already drawn) workpiece W from the function liquid droplet ejection apparatus 3 so as to transport it outside the imaging unit 2. The robot arm 15 is accessible to the function liquid droplet ejection apparatus 3 in the chamber main body 11 through the foregoing open/close door, and the workpiece W is accordingly introduced or retrieved into or from the function liquid droplet ejection apparatus 3 by inserting the robot arm 15 into the chamber main body 11 through the open/close door. The control unit 5 is configured by a personal computer and so forth and includes a monitor display and a variety of drives such as a compact disc (CD) drive and a digital versatile disc (DVD) drive other than its main body.

An installation space 18 shown in the figure is used for installing a drying apparatus, whereby the drying apparatus for drying (vaporizing) a function liquid solvent of function liquid ejected on the workpiece W depending on the situation can be installed in the corresponding imaging unit 2.

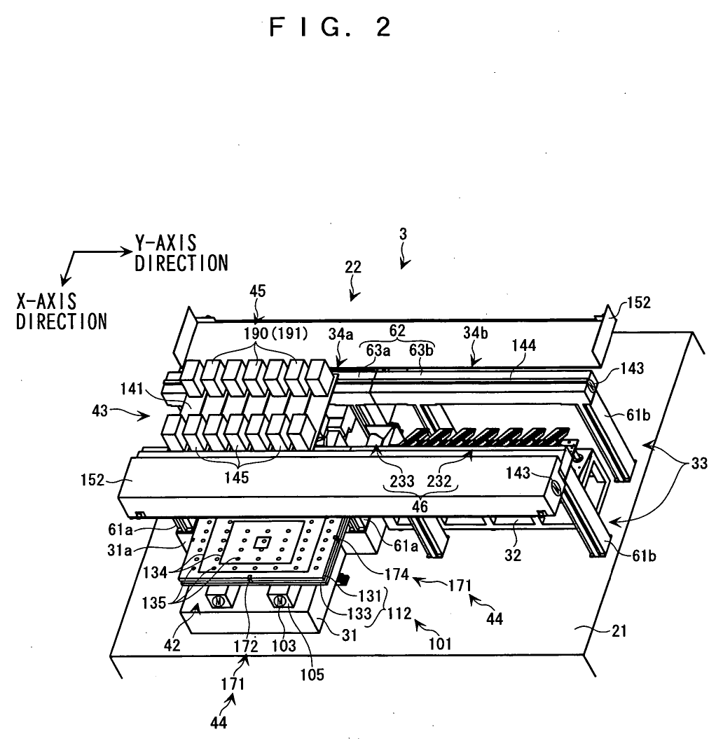

The function liquid droplet ejection apparatus 3 serving as the major part of this invention will be described. As shown in FIGS. 2 to 5, the function liquid droplet ejection apparatus 3 includes a large-sized common bed 21 installed on the floor and an apparatus main body 22 widely disposed on the common bed 21. As shown in the figures, the common bed 21 has a stone surface plate 31 and an angle frame 32 disposed thereon, in addition to having a pair of support stands 33 disposed thereon in a standing manner, composed of four stands 34a and 34b in two sets.

As shown in FIGS. 2 to 5, the apparatus main body 22 includes a head unit 41 including the function liquid droplet ejection heads 72 and a set table 101 directly disposed on the stone surface plate 31 and setting the workpiece W thereon. Also, the apparatus main body 22 includes: workpiece moving means (an X-axis table) 42 moving the workpiece in the X-axis direction (in the main scanning direction) through the set table 101; head-moving means (a Y-axis table) 43 disposed on the pair of support stands 33 and moving the head unit 41 in the Y-axis direction (in the sub-scanning direction); workpiece feeding/removing means 44, whose main part is disposed on the set table 101, lifting up the workpiece W when the workpiece W is fed on or removed from the set table 101, and eliminating static electricity of the workpiece W; function liquid feeding means 45 feeding function liquid to the head unit 41 (the function liquid droplet ejection heads 72); and maintenance means 46, whose main part is disposed on the angle frame 32, performing maintenance of the head unit 41 (the function liquid droplet ejection heads 72).

Although not shown in the figures, the apparatus main body 22 also includes: fluid feeding/recovering means feeding liquid (function liquid and cleaning liquid) and recovering the unnecessary liquid to and from each means; and air feeding means feeding compressed air for driving and controlling each means; air sucking means for sucking and setting the workpiece W; and so forth. The workpiece W introduced into the function liquid droplet ejection apparatus 3 is a transparent substrate (a glass substrate) having dimensions of 1800 mm long and 1500 mm wide and transversely set on the set table 101 and has a pixel area previously formed therein, which will be described later and in which coloring layers are formed.

In the function liquid droplet ejection apparatus 3, function liquid is ejected in the pixel area of the workpiece W by driving the function liquid droplet ejection heads 72 in a manner synchronized with driving of the workpiece moving means 42 so as to perform an imaging process (a liquid droplet ejection process) on the workpiece W. That is, imaging means is made up of the head unit 41 and the workpiece moving means 42. Meanwhile, in the non-imaging time of exchanging the workpiece with new one, for example, the head-moving means 43 is driven to arrange the head unit 41 so as to face the maintenance means 46 (through a carriage 75, which will be described later), and a maintenance process of the function liquid droplet ejection heads 72 is performed by the maintenance means 46. As described above, the function liquid droplet ejection apparatus 3 is accommodated in the chamber apparatus 6, whereby most of processes including an imaging process and the maintenance process are performed in the chamber apparatus 6.

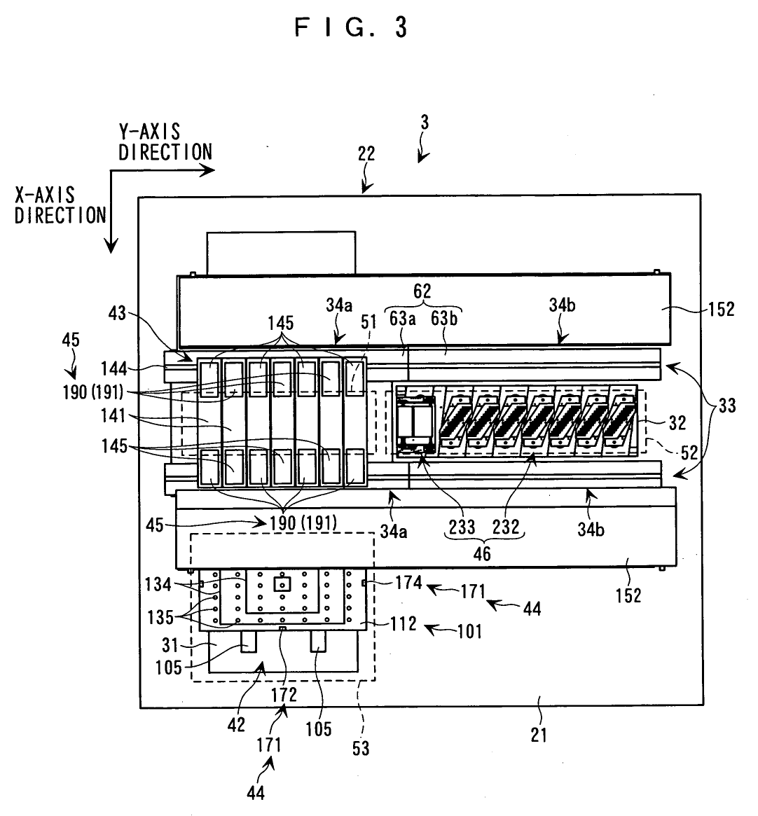

As shown in FIG. 3, an area formed by the moving trajectory of the workpiece W with the workpiece moving means 42 and that of the head unit 41 with the head-moving means 43 serves as an imaging area 51 in which an imaging process is performed. Also, an area on the moving trajectory of the head unit 41 with the head-moving means 43, facing the maintenance means 46, serves as a maintenance area 52 in which a maintenance process is performed. The maintenance area 52 also serves as a head-exchanging area in which the head unit 41 is exchanged with new one. In addition, the near side area of the workpiece moving means 42 in the figure serves as a workpiece carrying-in/out area 53 in which the workpiece W is carried in, or carried out of, the function liquid droplet ejection apparatus 3, and the foregoing workpiece carrying-in/out apparatus 4 is disposed so as to face the workpiece carrying-in/out area 53.

Each component of the function liquid droplet ejection apparatus 3 will be described. As shown in FIGS. 2 to 5, the stone surface plate 31 has an approximately rectangular parallelepiped shape and extends in the X-axis direction. Also, the stone surface plate 31 includes an extension 31a extending right and left from the central part thereof in the Y-axis direction, thus forming a shape of a modified cross in plan view. The angle frame 32 is formed by building angle members in a square shape and is juxtaposed to the extension 31a of the stone surface plate 31 in the Y-axis direction.

As shown in these figures, the pair of support stands 33 are disposed side by side in the X-axis direction (in the front and back direction) so as to sandwich the angle frame 32. Each support stand 33 extends in the Y-axis direction over the arranging range of the stone surface plate 31 and the angle frame 32 and includes four columns 61 in two sets aligned in the Y-axis direction and a column-shaped support member 62 bridging over the four columns 61. In other words, the pair of support stands 33 includes the eight columns 61 in four sets and the two column-shaped support members 62. While the lengths of the columns 61 in two sets of each support stand 33 are different from one another, the shorter columns in one set and the taller columns in anther set are respectively disposed on the extension 31a of the stone surface plate 31 and on the common bed 21 in a standing manner so that the four columns 61 in two sets are level with one another.

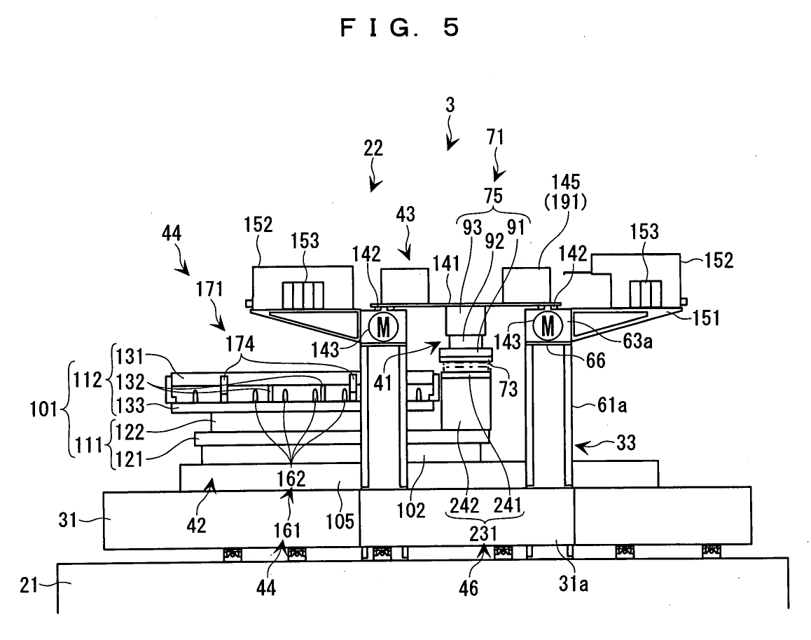

The column-shaped support member 62 is made up of two blocks 63a and 63b having the same end surfaces as each other and composed of a stone. The block 63a is installed over the two columns 61a disposed on the stone surface plate 31 in a standing manner so as to lie parallel to the Y-axis direction. Likewise, the block 63b is installed over the two columns 61b disposed on the common bed 21 in a standing manner so as to lie parallel to the Y-axis direction. That is, the stand 34a is made up of the two columns 61a and the block 63a, and the stand 34b is made up of the two columns 61b and the block 63b. Both blocks 63a and 63b are connected to each other in a state in which the end faces thereof abut against each other in the Y-axis direction and also fixed on the columns 61a and 61b. Thus, the column-shaped support member 62 is made up of the blocks 63a and 63b disposed side by side in the Y-axis direction. Each column 61 and each column-shaped support member 62 may have a level-adjusting plate 66 interposed therebetween so as to adjust the level of the upper surface of the column-shaped support member 62 (see FIG. 5).

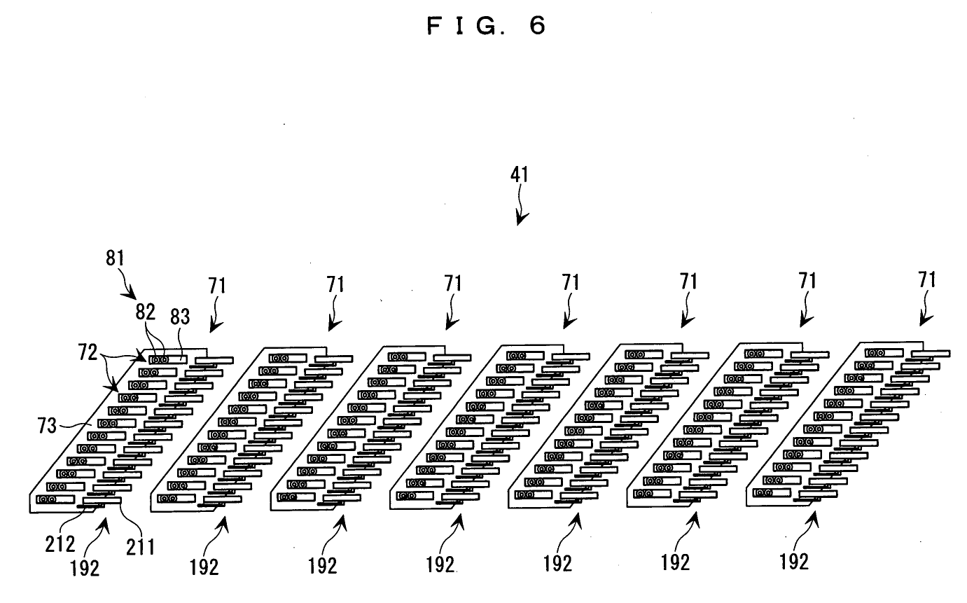

Each means of the apparatus main body 22 will be described. As shown in FIG. 6, the head unit 41 is made up of a plurality of (seven) divided head units 71 aligned in the Y-axis direction. As shown in FIGS. 5, 6, and 8, each divided head unit 71 includes: the twelve function liquid droplet ejection heads 72; a head plate 73 supporting the twelve function liquid droplet ejection heads 72; twelve holding members 74 fixing the corresponding function liquid droplet ejection heads 72 to the head plate 73; and the carriage 75 supported by the foregoing head-moving means 43 and also supporting the head plate 73.

In other words, a carriage unit is made up of the carriage 75 and the head plate 73 supported by the carriage 75. The carriage unit is suspended from a bridge plate 141, which will be described later, of the head-moving means 43, and the head-moving means 43 allows each of the seven carriage units to be independently movable in the Y-axis direction (in one direction).

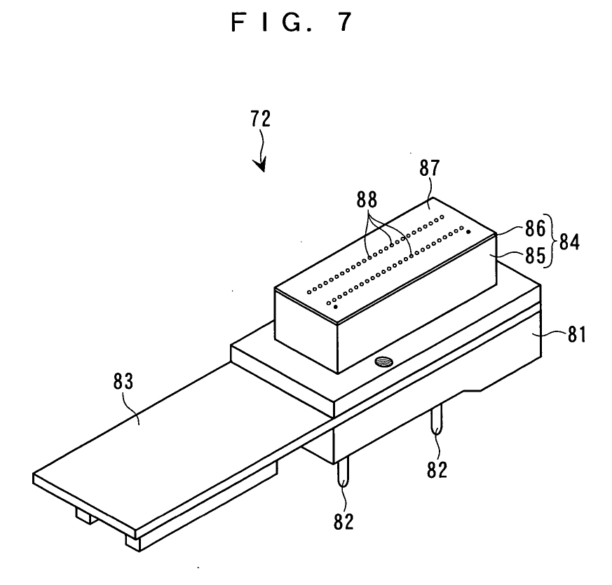

As shown in FIG. 7, the function liquid droplet ejection head 72 is of a so-called duplex type and includes: a function liquid introduction section 81 including duplex connecting needles 82; a duplex head substrate 83 in connection to the function liquid introduction section 81; and a head main body 84 connected to the lower part of the function liquid introduction section 81 and having a fluid path formed therein, filled with function liquid. The connecting needles 82 are connected to a function liquid tank 201 (not illustrated in the figure), which will be described later, and feed function liquid to the fluid path in the function liquid droplet ejection head 72. The head main body 84 is made up of a cavity 85 (a piezoelectric element) and a nozzle plate 86 including a nozzle surface 87 having discharge nozzles 88 perforated therein. The nozzle surface 87 has two rows of a large number (180) of the discharge nozzles 88 formed therein. When the function liquid droplet ejection head 72 is driven for ejection, the discharge nozzles 88 discharge function liquid in accordance with a pumping operation of the cavity 85.

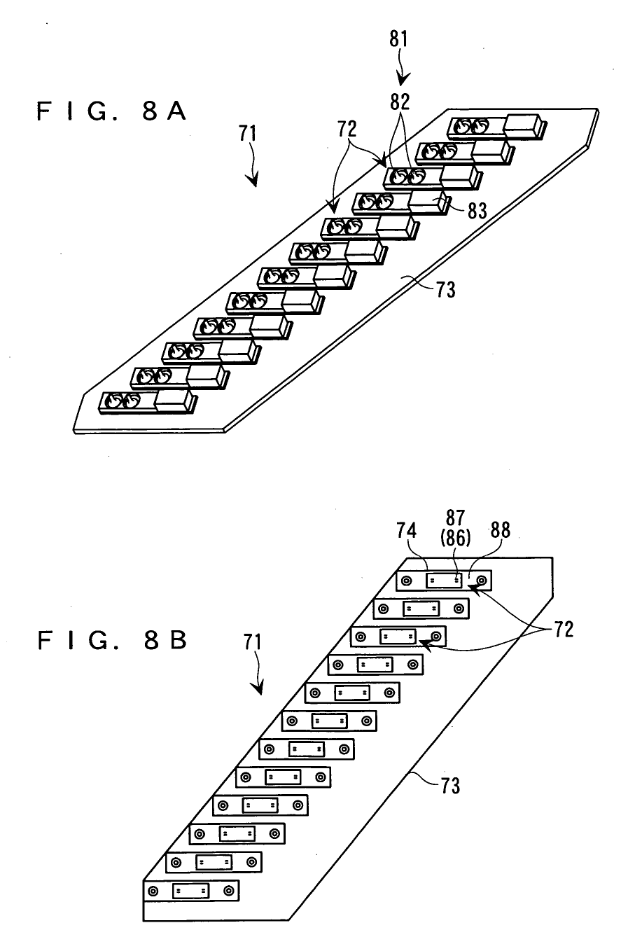

As shown in FIGS. 6 and 8, the head plate 73 is formed of a thick plate composed of stainless steel or the like and having an approximately parallelogram in plan view. The head plate 73 has twelve fixing perforations (not illustrated) formed therein for positioning the twelve function liquid droplet ejection heads 72 so as to fix them to the back surface thereof through the respective holding members 74. The twelve perforations formed in each head plate 73 are arranged in a row in a state of being displaced both in the X-axis and Y-axis directions. With this arrangement, each function liquid droplet ejection head 72 is fixed such that the nozzle rows lie in parallel to the Y-axis direction, and also, the twelve function liquid droplet ejection heads 72 make up a group of the liquid droplet ejection heads in a row and are disposed on the head plate 73 in a stepwise manner such that parts of the nozzle rows thereof overlap with one another in the Y-axis direction. That is, a single divided imaging line (a partial imaging line) is formed by the nozzle row (the discharge nozzles 88) of the group of the liquid droplet ejection heads (the twelve function liquid droplet ejection heads 72) mounted on each divided head unit 71.

As shown in FIG. 5, the carriage 75 includes: a carriage main body 91 detachably supporting the head plate 73; a θ-rotation mechanism 92 fixed on the upper surface of the carriage main body 91 (i.e., on the upper surface of the head plate 73) for performing positional correction with respect to the θ angular direction; and hanging members 93 having an I-shaped appearance, hanging the carriage main body 91 therefrom through the θ-rotation mechanism 92, and fixedly supported by the head-moving means 43.

Although not shown in the figure, the carriage main body 91 has a positioning mechanism disposed thereon for positioning the head plate 73. With this arrangement, the head unit 41 has the seven divided head units 71 aligned in the Y-axis direction (see FIG. 6). That is, in the Y-axis direction, each function liquid droplet ejection head 72 of the divided head unit 71 is arranged so as to align with the other six function liquid droplet ejection heads 72 having the respectively corresponding positional relationships with one another (i.e., lying at the same arrangement position). In other words, when the head plates 73 are positioned, twelve rows of function liquid ejection heads made up of the seven function liquid droplet ejection heads 72 having the respectively corresponding positional relationships with one another are disposed side by side in the X-axis direction in a state of being displaced in the Y-axis direction.

When the seven divided head units 71 are aligned, each head plate 73 is supported in a state of being positioned such that seven divided imaging lines of the respective divided head units 71 form a continuous single imaging line corresponding to the imaging width of the workpiece W in the Y-axis direction. More particularly, each divided imaging line is defined as one of seven parts of a single imaging line divided so as to be allotted to the respective divided head units 71. When the seven divided head units 71 are aligned, the head plate 73 are aligned, whereby a single imaging line consisting of seven divided imaging lines (i.e., made up of the nozzle rows of 12×7 function liquid droplet ejection heads 72) is formed. The single imaging line is previously determined at 1800 mm, corresponding to the length of the long side of the workpiece W so as to cope with any of longitudinal and transverse placements of the workpiece W. A position at which the head unit 41 faces (i.e., all divided head units 71 face) the imaging area 51, and a single imaging line is formed, serves as an imaging home position of the head unit 41, and the imaging process of the workpiece W is performed at this position.

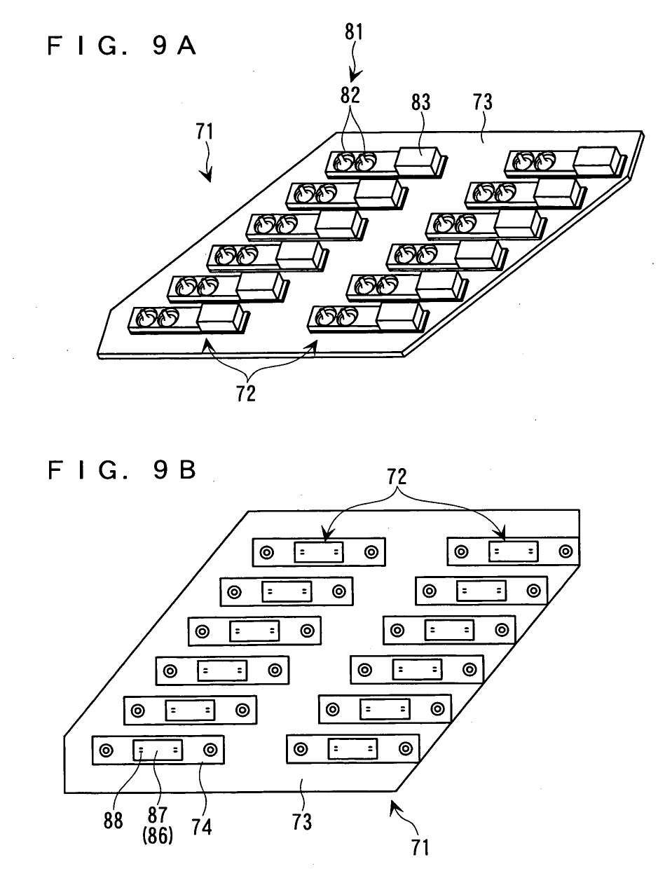

As long as the nozzle rows (the discharge nozzles 88) of each function liquid droplet ejection head 72 mounted on the head plate 73 are capable of continuously forming a divided imaging line in the Y-axis direction, a method of arranging the function liquid droplet ejection heads 72 on the head plate 73 is arbitrary. In this embodiment, although the twelve function liquid droplet ejection heads 72 are arranged on the head plate 73 such that parts of the nozzle rows thereof overlap with each other in the Y-axis direction, instead of the foregoing overlapping arrangement, the twelve function liquid droplet ejection heads 72 may be arranged such that a single imaging line is formed by all discharge nozzles 88 of the twelve function liquid droplet ejection heads 72. Also, as shown in FIG. 9, the twelve function liquid droplet ejection heads 72 may be arranged in a manner of being divided into two rows (a plurality of rows). When a plurality of the function liquid droplet ejection heads 72 are arranged in a manner of being divided into a plurality of rows, the head plate 73 has a shorter width in the X-axis direction. Likewise, as long as a single imaging line can be formed, the divided head units 71 may be arbitrarily arranged. As a matter of course, for example, the numbers of the function liquid droplet ejection heads 72 mounted on each divided head unit 71 and the divided head units 71 can be arbitrarily set according to the actual conditions.

As shown in FIGS. 2 to 5, the workpiecepiece moving means 42 includes: the set table 101 on which the workpiecepiece W is set; an X-axis air slider 102 slidably supporting the set table 101 in the X-axis direction; a pair of right and left X-axis linear motors 103 extending in the X-axis direction and moving the workpiecepiece W in the X-axis direction through the set table 101; a pair of X-axis guide rails (not illustrated) juxtaposed to the X-axis linear motors 103 and guiding the movement of the X-axis air slider 102; and an X-axis linear scale 104 (not illustrated) for detecting the position of the set table 101.

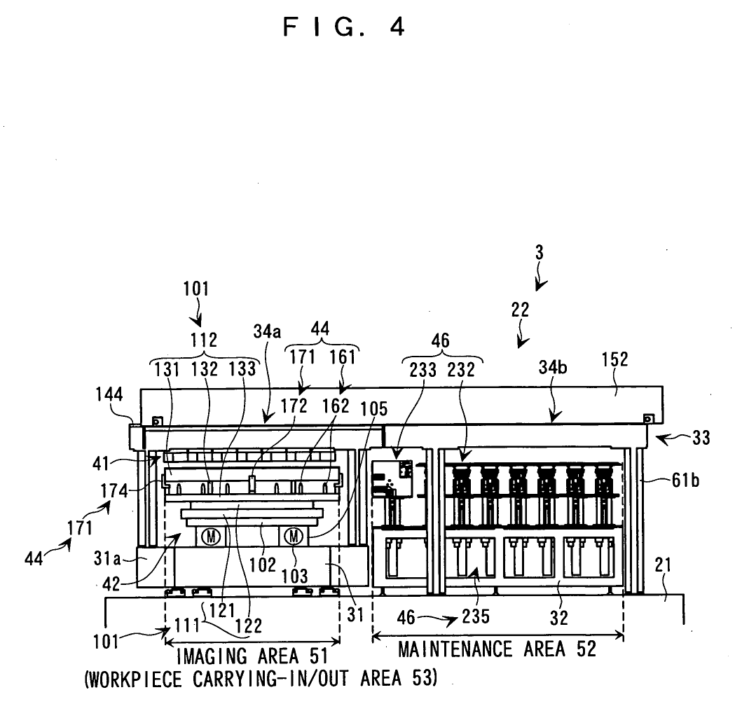

As shown in FIGS. 4 and 5, the set table 101 has a structure in which an absorption table 112 absorbing the workpiecepiece W is built on a θ-table 111 supported by the X-axis air slider 102. The θ-table 111 includes: a θ-fixing section (a table base) 121 fixed to the X-axis air slider 102; and a θ-rotation section 122 (a rotating table) supporting the absorption table 112 and also rotatably (about the θ-angular axis) supported by the θ-fixing section 121 and finely adjusts (corrects) the θ-angular position of the workpiecepiece W by rotating the workpiece W about the θ-angular axis through the suction table 11. The θ-fixing section 121 supports a flushing unit 231 of the maintenance means 46, which will be described later.

The absorption table 112 includes: a table main body 131 absorbing the workpiece W; three sets of table-supporting members 132 supporting the table main body 131; and a support base 133 fixed to the θ-table 111 and supporting the table main body 131 through the table-supporting members 132. The table main body 131 is composed of a thick stone board and has an approximately square shape in plan view. The table main body 131 has a 1800-mm side, corresponding to the length of the long side of the workpiece W so that the workpiece W can be set at an arbitrary orientation of either longitudinal or transverse placement. As shown in FIGS. 2 and 3, the table main body 131 has a plurality of suction grooves 134 formed on the upper surface thereof for sucking the workpiece W. Each suction groove 134 has suction holes (not illustrated) formed therein, in communication with the foregoing air sucking means. The workpiece W thus undergoes a sufficient sucking force through the suction grooves 134.

The three sets of the table-supporting members 132 support the table main body 131 at three points such that the rotating axis (the θ-axis) of the θ-table 111 agrees with the center of gravity of the table main body 131. As will be described later in detail, the absorption table 112 has a lift-up mechanism 161 and a pre-alignment mechanism 171 of the workpiece feeding-removing means 44 built therein. The support base 133 has major parts of the lift-up mechanism 161 and the pre-alignment mechanism 171 disposed thereon, and the table main body 131 has a plurality of through-holes 135 formed therein in an aligned manner, for allowing the plurality of lift-up pins 162 of the lift-up mechanism 161 to pass therethrough.

The X-axis linear motors 103, the pair of X-axis guide rails, and the X-axis linear scale 104 are directly placed on the foregoing stone surface plate 31. When driven in a synchronized manner with each other, the pair of X-axis linear motors 103 moves the X-axis air slider 102 in the X-axis direction while guiding the pair of X-axis guide rails. The workpiece W set on the set table 101 thus moves in the X-axis direction. Since the pair of X-axis guide rails has the X-axis linear scale 104 interposed therebetween, an ejection timing of the function liquid droplet ejection heads 72 is determined on the basis of the measured results of the X-axis linear scale 104. The pair of X-axis linear motors 103, the pair of X-axis guide rails, and the X-axis linear scale 104 are accommodated in a pair of X-axis accommodation boxes 105.

As shown in FIGS. 2 to 5, the head-moving means 43 bridges the imaging area 51 and the maintenance area 52 and also moves the head unit 41 between the imaging area 51 and the maintenance area 52. The head-moving means 43 includes: the seven bridge plates 141 supporting the respective seven divided head units 71; seven sets of Y-axis sliders 142 supporting the seven bridge plates 141 at both end thereof so as to be aligned in the Y-axis direction; a pair of Y-axis linear motors 143 extending in the Y-axis direction and move the seven bridge plates 141 in the Y-axis direction through the seven sets of Y-axis sliders 142; a pair of Y-axis guide rails (Linear Motion (LM) guides, made by THK co., Ltd.) 144 extending in the Y-axis direction and guiding the moves of the seven bridge plates 141; and a Y-axis linear scale 146 (not illustrated) detecting the moving position of the head unit 41 (the function liquid droplet ejection heads 72) through the carriage 75.

As shown in FIG. 5, the bridge plates 141 have through-holes (not illustrated) perforated therein for positioning the carriage 75 and fix the carriage 75 (the hanging members 93) thereto by passing the carriage 75 (the hanging members 93) through the through-holes. Also, each bridge plate 141 has a head-use electrical unit 145 mounted thereon for driving the function liquid droplet ejection heads 72 of the divided head units 71 (see FIGS. 2 and 3). The seven head-use electrical units 145 are arranged in a stagger pattern so that mutual interference of the head-use electrical units 145 on the mutually adjacent bridge plates 141 is avoided and that the bridge plates 141 are effectively arranged.

One of the pair of Y-axis linear motors 143 and one of the pair of Y-axis guide rails 144 are directly disposed to the column-shaped support member 62 of one of the foregoing pair of support stands 33. Also, the Y-axis linear scale 146 is directly disposed to one of the pair of column-shaped support member 62. In the head-moving means 43 according to this embodiment, by driving the pair of Y-axis linear motors 143 so as to simultaneously move the seven sets of Y-axis sliders 142 in the Y-axis direction, the head unit 41 made up of the seven divided head units 71 is moved as a united body (in a state in which a single imaging line is formed) in the Y-axis direction. By selectively driving the pair of Y-axis linear motors 143 so as to independently move the seven sets of Y-axis sliders 142, the divided head units 71 can be independently moved in the Y-axis direction.

As shown in FIG. 5, each column-shaped support member 62 has a pair of brackets 151 fixed outwardly on the side surfaces thereof, and the pair of brackets 151 have respective Y-axis accommodation boxes 152 supported thereon. That is, the pair of Y-axis accommodation boxes 152 are juxtaposed to the pair of column-shaped support members 62. The pair of Y-axis accommodation boxes 152 have two groups of seven Y-axis cable carriers 153 (Cableveyor: registered trade mark, made by Tsubakimoto Chain Co.) accommodated therein, corresponding to the independently movable seven divided head units 71 and accommodating a tube, a cable, and so forth connected to each divided head unit 71 (the head-use electrical unit 145) so as to follow the movement of the divided head unit 71. In this case, for corresponding to the seven head-use electrical units 145 disposed in two groups, the seven Y-axis cable carriers 153 are preferably disposed into two groups of four and three carriers.

An imaging process will be described. Prior to the imaging process, the head-moving means 43 is driven so as to move the head unit 41 to the imaging area 51 (the imaging home position). With the workpiece carrying-in/out apparatus 4, an unprocessed workpiece W is introduced onto the set table 101 lying in the workpiece carrying-in/out area 53. When the workpiece W is set on the set table 101, the workpiece moving means 42 is driven so as to move the workpiece W forwardly in the main scanning (the X-axis) direction. In a manner synchronized with the forward movement of the workpiece W, the function liquid droplet ejection heads 72 are selectively driven so as to selectively eject function liquid (so as to perform a selective ejection operation (an imaging process) onto the workpiece W.

As described above, since a single imaging line of the head unit 41 is previously formed so as to correspond to the length of the long side of the workpiece W, the imaging process of a single sheet of the workpiece W can be completed with a single forward movement of the workpiece W regardless of longitudinal or transverse placement of the workpiece W. After the single forward movement of the workpiece, the workpiece moving means 42 is subsequently driven so as to backwardly move the workpiece W. The drawn workpiece W is thus moved to the workpiece carrying-in/out area 53 for retrieval from the set table 101 by the workpiece carrying-in/out apparatus 4.

Although the workpiece W is directly moved with respect to the head unit 41 in this embodiment, the head unit 41 may be moved with respect to the fixed Workpiece. Also, the function liquid droplet ejection heads 72 may be driven for ejection at the time of not only forward moving but also backward moving of the workpiece W so as to complete the imaging process with a single of reciprocal movement. In addition, the imaging process can be performed with the head unit 41 having a structure in which a single imaging line is shorter than one side (imaging width) of the workpiece W. In this case, the imaging process is achieved by alternately performing the main scanning with which a single imaging line is drawn while moving the workpiece W and the sub-scanning with which the head unit 41 is moved in the Y-axis direction by an amount of a single imaging line after performing the main scanning.

As described above, the X-axis linear motors 103, the X-axis guide rails, and the X-axis linear scale 104 of the workpiece moving means 42 are directly supported on the stone surface plate 31. Also, the Y-axis linear motors 143, the Y-axis guide rails 144, and the Y-axis linear scale 146 of the head-moving means 43 are directly supported by the column-shaped support members 62 composed of stone. Since the major parts of the head-moving means 43 and the workpiece moving means 42 are disposed on the stone-made components easily offering good flatness and also having a small coefficient of thermal expansion as described above, the workpiece W and the head unit 41 can be accurately moved, whereby the workpiece W is subjected to an accurate imaging process.

The workpiece feeding-removing means 44 will be described. The workpiece feeding-removing means 44 is provided for setting (introducing) the unprocessed workpiece W carried in the workpiece carrying-in/out area 53 on the set table 101 and also for retrieving the processed workpiece W from the set table 101 and includes the lift-up mechanism 161, the pre-alignment mechanism 171, and static eliminating means 181.

As shown in FIGS. 4 and 5, the lift-up mechanism 161 is aligned in the X-axis and Y-axis directions and includes the plurality of lift-up pins 162 protruding or retracting from the corresponding through-holes 135 perforated in the absorption table 112 (the table main body 131). When the unprocessed workpiece W is to be placed on the set table 101, the plurality of lift-up pins 162 is protruded from the absorption table 112 and is retracted into the absorption table 112 after the lift-up mechanism 161 receives the workpiece W from the robot arm 15 of the workpiece carrying-in/out apparatus 4. On the other hand, when the workpiece W is to be retrieved from the absorption table 112, the lift-up pins 162 retracted in the absorption table 112 are raised so that the workpiece W is lifted up (detached) off the absorption table 112. The robot arm 15 faces the lifted-up workpiece W from below and retrieves it from the absorption table 112.

As shown in FIGS. 2 to 5, the pre-alignment mechanism 171 is provided for positioning (pre-aligning) the unprocessed workpiece W placed on the absorption table 112 by the lift-up mechanism 161 with respect to the table main body 131 and includes an X-axis positioning unit 172 for positioning the workpiece W in the back and forth direction thereof (in the X-axis direction) by sandwiching the front and rear ends of the workpiece W with a pair of X-sandwiching members (not illustrated) and a Y-axis positioning unit 174 for positioning the workpiece W in the right and left direction thereof (in the Y-axis direction) by sandwiching the right and left ends of the workpiece W with two sets of Y-sandwiching members (not illustrated).

The static eliminating means 181 is provided for eliminating static electricity charged on the rear surface of the workpiece W by irradiating the workpiece W with soft X-rays and is made up of an ionizer, for example. The static eliminating means 181 is disposed so as to face the workpiece carrying-in/out area 53 and faces the workpiece which is moved from the robot arm 15 to the lift-up mechanism 161 or which is lifted up (detached) off the absorption table 112 such that static electricity on the workpiece W is effectively eliminated.

The function liquid feeding means 45 will be described. The function liquid feeding means 45 is made up of seven function liquid feeding units 190 corresponding to the seven divided head units 71, each unit 190 feeding function liquid to the corresponding divided head unit 71 (see FIGS. 2 and 3). Each function liquid feeding unit 190 includes: a tank unit 191 including a plurality (twelve) of the function liquid tanks 201 storing function liquid; a plurality of (twelve) of function liquid feeding tubes 193 connecting each of the function liquid tank 201 to the corresponding function liquid droplet ejection head 72; and a valve unit 192 including a plurality of (twelve) pressure regulators 211 disposed in the plurality of function liquid feeding tubes 193.

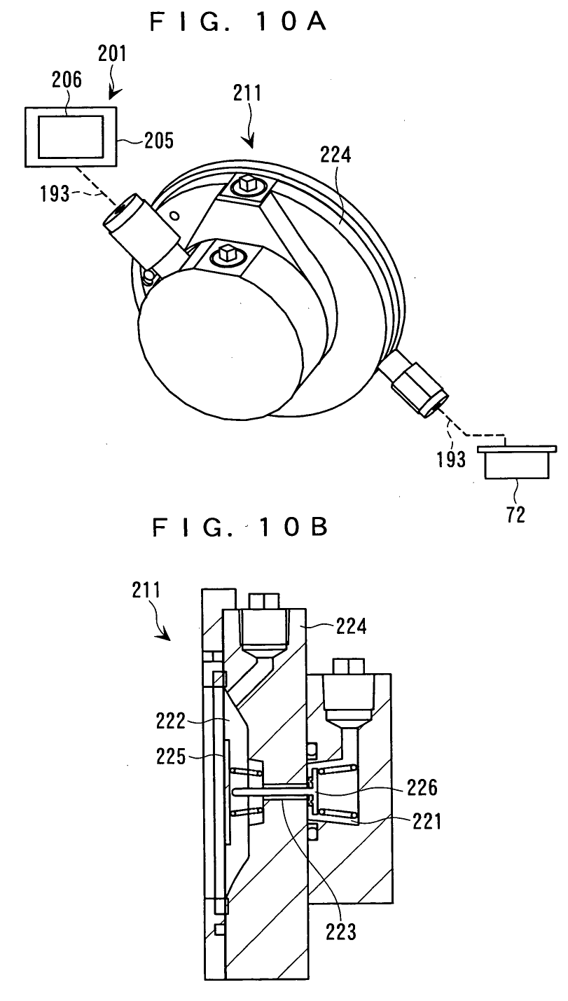

As shown in FIGS. 2 and 3, the tank unit 191 is disposed on the corresponding bridge plate 141 so as to face the head-use electrical unit 145 having the corresponding through-hole interposed therebetween. The twelve function liquid tanks 201 disposed in the tank unit 191 are connected to the respective twelve function liquid droplet ejection heads 72 mounted on the divided head unit 71 (through the twelve function liquid feeding tubes 193). The function liquid tank 201 is of a cartridge type in which a function liquid pack 206 having a function liquid vacuum-packed therein is contained in a resin-made cartridge casing 205, and the function liquid pack 206 stores previously deaerated function liquid (see FIG. 10).

As shown in FIG. 6, the valve unit 192 includes the twelve pressure regulators 211 and twelve fixing members 212 fixing the twelve pressure regulators 211 to the corresponding head plate 73. As shown in FIG. 10, the pressure regulator 211 has a structure in which a first chamber 221 in communication with the function liquid tank 201, a second chamber 222 in communication with the function liquid droplet ejection head 72, and a communication flow-path 223 communicating the first and second chambers 221 and 222 with each other are formed in a valve housing 224. The second chamber 222 has a diaphragm 225 outwardly disposed on one surface thereof, and the communication flow-path 223 has a valve disk 226 disposed thereon, performing an open-close action with the diaphragm 225. When function liquid introduced into the first chamber 221 from the function liquid tank 201 is fed to the function liquid droplet ejection head 72 through the second chamber 222, the diaphragm 225 is displaced with a predetermined adjusting reference pressure (in this case, the atmospheric pressure), whereby the valve disk 226 disposed on the communication flow-path 223 performs an open-close action such that the pressure in the second chamber 222 is adjusted so as to contain function liquid having a slightly negative pressure.

By disposing the pressure regulator 211 having the above-described structure between the function liquid tank 201 and the function liquid droplet ejection head 72, function liquid can be fed to the function liquid droplet ejection head 72 without influence of the hydraulic head of the function liquid tank 201. More particularly, since the feeding pressure of function liquid is determined in accordance with a height difference in positions of the function liquid droplet ejection head 72 (the nozzle surface 87) and the pressure regulator 211 (the center of the diaphragm 225), it can be held at a predetermined pressure by making the height difference at a predetermined value. When the valve disk 226 is closed, the first and second chambers 221 and 222 are not in communication with each other, thereby the pressure regulator 211 has a damper function for absorbing fluctuations or the like generated in the function liquid tank (at the primary side).

As shown in FIG. 6, the twelve fixing members 212 are disposed on the head plate 73 such that thee members are displaced in the Y-axis direction in the similar manner to the arrangement of the function liquid droplet ejection heads 72 of the divided head unit 71, By disposing the pressure regulators 211 in the similar manner to the arrangement of the function liquid droplet ejection heads 72 as described above, the length of the function liquid feeding tube 193 between the function liquid droplet ejection head 72 and the pressure regulator 211 can be made constant, whereby each function liquid droplet ejection head 72 can be provided with function liquid having a substantially constant feeding pressure.

Although the tank unit 191 is disposed on the bridge plate 141 in this embodiment, it may be disposed on the head plate 73. In this case, the length of the function liquid feeding tube 193 (i.e., function liquid flow-path) from the function liquid tank 201 to the function liquid droplet ejection head 72 can be shorten, thereby leading to effective use of function liquid. Also, the valve unit 192 is not limited to the arrangement of the head plate 73, and it may be disposed on the bridge plate 141 according to the actual conditions.

The maintenance means 46 will be described. The maintenance means 46 is provided mainly for performing maintenance of the function liquid droplet ejection heads 72 and includes the flushing unit 231, suction units 232, a wiping unit 233, and unit-elevation mechanisms 235. As shown in FIG. 5, the flushing unit 231 is juxtaposed to the set table 101. The suction units 232, the wiping unit 233, and the unit-elevation mechanisms 235 are supported by the angle frame 32 (see FIGS. 2 to 4, 11, and 12).

Preferably, the maintenance means 46 includes discharge-checking units and weight-measuring units respectively checking the flying state and measuring the weight of a function droplet ejected from each function liquid droplet ejection head 72, and so forth, in addition to including the above-described units.

The flushing unit 231 is provided for receiving function liquid ejected in accordance with a flushing operation, that is, a preliminary discharge (a disposal discharge) of each function liquid droplet ejection head 72, in particular, for receiving function liquid ejected in accordance with a pre-discharge flushing operation performed immediately before ejecting function liquid onto the workpiece W. As shown in FIG. 5, the flushing unit 231 is disposed along the set table 101 and is made up of a flushing box 241 for receiving function liquid and a box-supporting member 242 fixed to the θ-fixing section 121 of the foregoing θ-table 111 and supporting the flushing box 241.

The flushing box 241 has a rectangular shape in plan view and has an absorber (not illustrated) absorbing function liquid, disposed on the rear surface thereof. The flushing box 241 is formed such that the short side thereof corresponds to the length of the head unit 41 in the X-axis direction and the long side thereof coincides with the length of one side of the table main body 131 (the length of a single imaging line). In other words, the flushing box 241 is formed so as to include the head unit 41 and can receive function liquid at once flushed from all function liquid droplet ejection heads 72 mounted on the head unit 41.

The box-supporting member 242 supports the flushing box 241 along the side of the set table 101 (the absorption table 112) being perpendicular to the X-axis and lying on the opposite side (the rear side in the figure) of the foregoing workpiece carrying-in/out area 53. That is, since the flushing box 241 is disposed along the side of the absorption table 112 serving as the leading side at the time of forward moving of the workpiece W, when the workpiece W is moved in the X-axis direction, the head unit 41 faces the flushing unit 231 and then the workpiece W. Accordingly, moving of the head unit 41 only for a pre-discharge flushing operation is not needed and also the pre-discharge flushing operation can be performed immediately before facing the workpiece W. Also, lying in the rear of the workpiece carrying-in/out area 53, the flushing box 241 does not disturb introduction or retrieval of the workpiece W when it is introduced into or retrieved from the set table 101. When the set table 101 is arranged so as to face the workpiece carrying-in/out area 53, the flushing box 241 is supported so as to face the imaging area 51 and lies directly below the head unit 41 (see FIG. 5, for example).

The box-supporting member 242 supports the flushing box 241 such that the upper surface of the flushing box 241 is substantially flush with that of the workpiece W set on the absorption table 112. Since the flushing box 241 is supported substantially in flush with the absorption table 112 as described above, the flushing box 241 does not interfere with the head unit 41 and effectively receives function liquid ejected in accordance with the flushing operation.

As described above, although the function liquid droplet ejection heads 72 are driven for ejection only at the time of forward movement of the workpiece W in this embodiment, when the function liquid droplet ejection heads 72 discharge function liquid also at the time of backward movement of the workpiece W, a pair of flushing boxes are preferably disposed along the two sides of the set table 101, being perpendicular to the X-axis. With this structure, the flushing operation can be performed immediately before discharge drive in accordance with reciprocal movement of the workpiece W.

Other than the foregoing pre-discharge flushing operation, flushing operations include a regular flushing operation performed when imaging onto the workpiece W is temporarily suspended, for example, at the time of replacement of the workpiece W, and, in this embodiment, function liquid ejected in accordance with this regular flushing operation is received by the suction units 232, which will be described later.

The suction units 232 are provided for sucking the function liquid droplet ejection heads 72 so as to forcefully expel function liquid from the same. The function liquid droplet ejection heads 72 are sucked by the suction units 232 not only for eliminating or preventing the clogging of nozzles thereof the function liquid droplet ejection heads 72 but also for filling function liquid in the function liquid flow-paths extending from the function liquid tank 201 to the function liquid droplet ejection heads 72 when the function liquid droplet ejection apparatus 3 is newly installed or the function liquid droplet ejection head 72 is replaced with new one.

As shown in FIGS. 2 to 4, 11, and 12, the suction units 232 are disposed next to the wiping unit 233 in the Y-axis direction and face the maintenance area 52 and are also formed so as to correspond to the seven divided head units 71 making up the head unit 41. More particularly, the suction units 232 include seven divided suction units 251 sucking the respective divided head units 71. The seven divided suction units 251 are aligned in the Y-axis direction in a similar manner to the arrangement of the seven divided head units 71 making up the head unit 41.

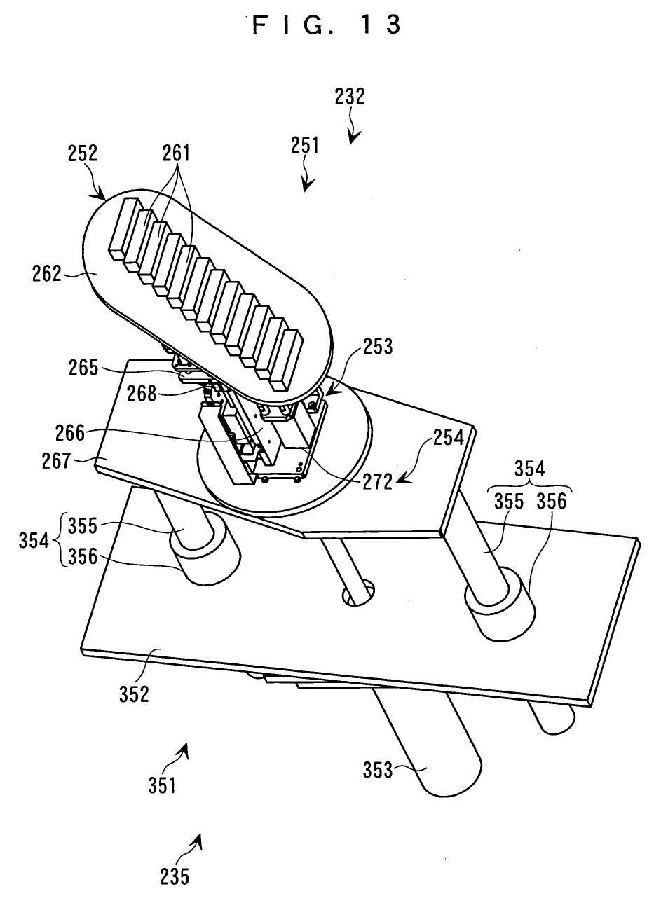

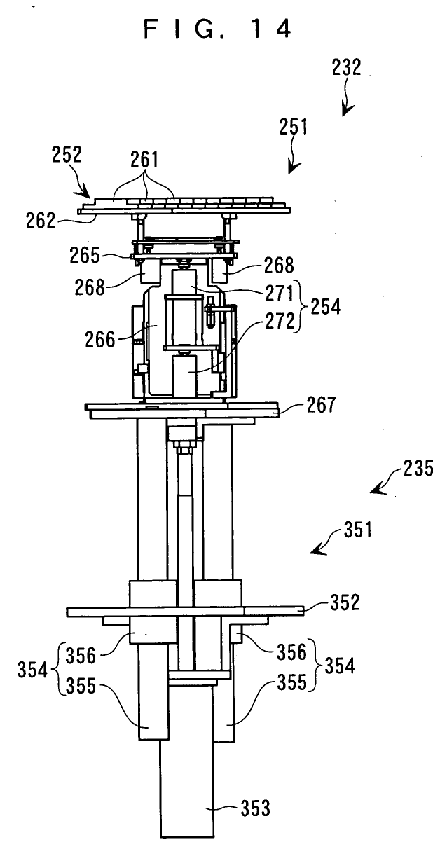

As shown in FIGS. 13 and 14, the seven divided suction units 251 are independently and elevatably supported by seven elevation mechanisms 351, which will be described later, of the foregoing unit-elevation mechanisms 235. As shown in these figures, each divided suction unit 251 faces the divided head unit 71 from below and includes: a cap unit 252 including caps 261, which are closely attached to the nozzle surfaces 87 of the function liquid droplet ejection heads 72; a cap-supporting member 253 supporting the cap unit 252; a cap-elevation mechanism 254 built in the cap-supporting member 253 and elevating the cap unit 252 through the cap-supporting member 253; and sucking means (not illustrated) exerting sucking forces on the function liquid droplet ejection heads 72 through the closely attached caps 261.

As shown in FIGS. 13 and 14, the cap unit 252 has a structure in which the twelve caps 261 are arranged on a cap base 262 so as to correspond to the arrangement of the function liquid droplet ejection heads 72 mounted on the divided head unit 71. More particularly, the suction units 232 have 12×7 (84) pieces of the caps 261 arranged therein in similar manner to the arrangement of the function liquid droplet ejection heads 72 of the head unit 41, whereby all function liquid droplet ejection heads 72 of the head unit 41 can be closely attached by the caps 261. Although not shown in the figures, each cap 261 has an air release valve disposed therein so as to suck function liquid remaining therein by opening the air release valve at the final stage of the sucking operation of the divided suction unit 251.

As shown in FIGS. 13 and 14, the cap-supporting member 253 includes a cap-supporting plate 265 supporting the cap unit 252, a cap stand 266 vertically slidably supporting the cap-supporting plate 265, and a cap-supporting base 267 supporting the cap stand 266. The cap-supporting plate 265 has a pair of air cylinders 268 fixed on the lower surface thereof, for opening or closing the air release valve (not illustrated) of the cap 261.

As shown in FIG. 14, the cap-elevation mechanism 254 includes: a first elevation cylinder 271 disposed above the cap stand 266 and elevatably supporting the cap unit 252 through the cap-supporting plate 265; and a second elevation cylinder 272 disposed below the cap stand 266 and elevatably supporting the cap unit 252 through the first elevation cylinder 271. The first and second elevation cylinders 271 and 272 are made up of air cylinders having different strokes from each other, and the stroke of the second elevation cylinder 272 is longer than that of the first elevation cylinder 271. Thus, by selectively driving the first and second elevation cylinders 271 and 272, the elevated position of the cap unit 252 can be switched between either one of a first position at which the caps 261 are closely attached to the function liquid droplet ejection heads 72 and a second position lying slightly lower than the first position (by an amount of about 2 to 3 mm). More particularly, when the first elevation cylinder 271 is driven, the cap unit 252 can be moved from a predetermined bottom position to the first position, and when the second elevation cylinder 272 is driven, the cap unit 252 can be moved to the second position.

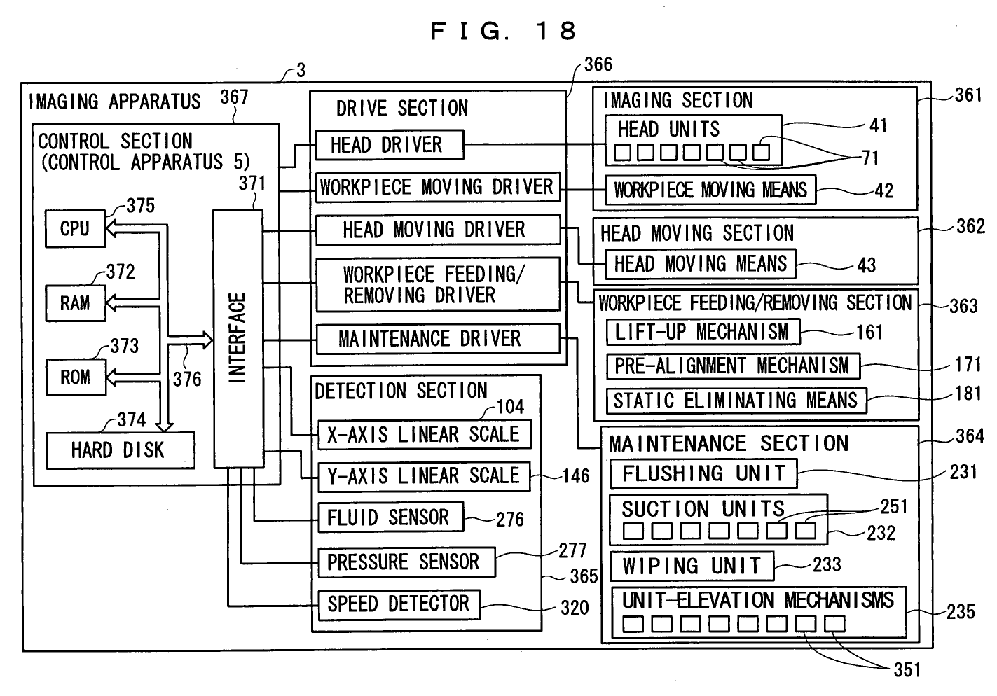

The sucking means includes a single ejector exerting a sucking force on the twelve function liquid droplet ejection heads 72 of the divided head unit 71 and suction tubes connecting the twelve caps 261 and the ejector (both not illustrated). The ejector is connected to the foregoing air feeding means with an air-feeding tube (not illustrated). The single suction tube connected to the ejector is branched into a plurality (twelve) of divided suction tubes (not illustrated) so as to be connected to the respective caps 261 with a header pipe (not illustrated). The suction tube has a reusing tank disposed therein, which will be described later, of the fluid feeding/recovering means, and function liquid sucked by the ejector is stored in the reusing tank. Although not shown in the figures, in the vicinity of the cap 261 of each divided suction tube, a fluid sensor (fluid detecting sensor) 276 (see FIG. 18) for detecting the presence of function liquid, a pressure sensor 277 (see FIG. 18) detecting the pressure in the divided suction tube, and a suction valve for opening or closing the divided suction tube are disposed in that order from the cap 261.

A sucking operation of the divided suction unit 251 will be described. Prior to the sucking operation, the head-moving means 43 is driven so as to move the head unit 41 in the maintenance area 52 such that one of the divided head units 71 is arranged so as to face the divided suction unit 251. Subsequently, the cap-elevation mechanism 254 is driven so as to move the cap unit 252 to the first position. With this operation, all function liquid droplet ejection heads 72 of the divided head unit 71 facing the divided suction unit 251 are closely attached by the corresponding caps 261. Then, the air feeding means feeds compressed air to the ejector so as to suck the function liquid droplet ejection heads 72 through the caps 261. When a given quantity of function liquid is sucked from each function liquid droplet ejection head 72, a feeding operation of compressed air to the ejector is suspended. When a sucking operation of the function liquid droplet ejection heads 72 is finished, the cap-elevation mechanism 254 is driven so as to move the cap unit 252 to the bottom position, thereby detaching the caps 261 off the function liquid droplet ejection heads 72.

During the sucking operation of function liquid, the operation is monitored in accordance with detected signals of the fluid sensor 276 and the pressure sensor 277 so as to detect poor suction of each cap 261. Also, by opening or closing the foregoing suction valve in accordance with the detected results of the fluid sensor 276 and the pressure sensor 277, an amount of function liquid sucked by each function liquid droplet ejection head 72 can be made substantially constant, thereby preventing the function liquid from being excessively sucked due to the sucking operation.

The suction unit 232 is provided not only for sucking the function liquid droplet ejection heads 72 as described above, but also for receiving function liquid ejected in accordance with the regular flushing operation. In other words, each cap 261 of the suction unit 232 serves also as the flushing box, whereby the cap 261 receives function liquid ejected by the corresponding function liquid droplet ejection head 72 during the regular flushing operation. In this case, the cap-elevation mechanism 254 is driven so as to elevate the cap unit 252 to the second position. With this operation, since the cap 261 is supported in a state of being detached off the nozzle surface 87 of the function liquid droplet ejection head 72 only by an amount of 2 to 3 mm, function liquid ejected in accordance with the regular flushing operation is effectively received by the cap 261.

The suction unit 232 can be also used for storing the function liquid droplet ejection heads 72, for example, in the non-imaging time of the function liquid droplet ejection apparatus 3. In this case, after the head unit 41 faces the maintenance area 52, the cap-elevation mechanism 254 is driven so as to move the cap unit 252 to the first position. With this operation, since the cap 261 is closely attached to the nozzle surface 87 of the function liquid droplet ejection head 72, the nozzle surface 87 is sealed (capped), thereby preventing the function liquid droplet ejection head 72 (the discharge nozzles 88) from being dried.

The wiping unit 233 will be described. The wiping unit 233 is provided for wiping the nozzle surface 87 of each function liquid droplet ejection head 72, having function liquid accreted thereto due to, for example, the sucking operation of the function liquid droplet ejection head 72 and getting dirty, by using a wiping sheet 281. As shown in FIGS. 2 to 4, 11, and 12, the wiping unit 233 is disposed at a part of the unit-elevation mechanisms 235, lying between the imaging area 51 and the suction units 232, that is, lying in a part of the foregoing maintenance area 52, close to the imaging area 51. With such an arrangement, the wiping unit 233 faces the divided head units 71 of the head unit 41 one after another, moving to the imaging area 51 after finishing the sucking operation thereof, whereby the function liquid droplet ejection heads 72 are subjected to a wiping process.

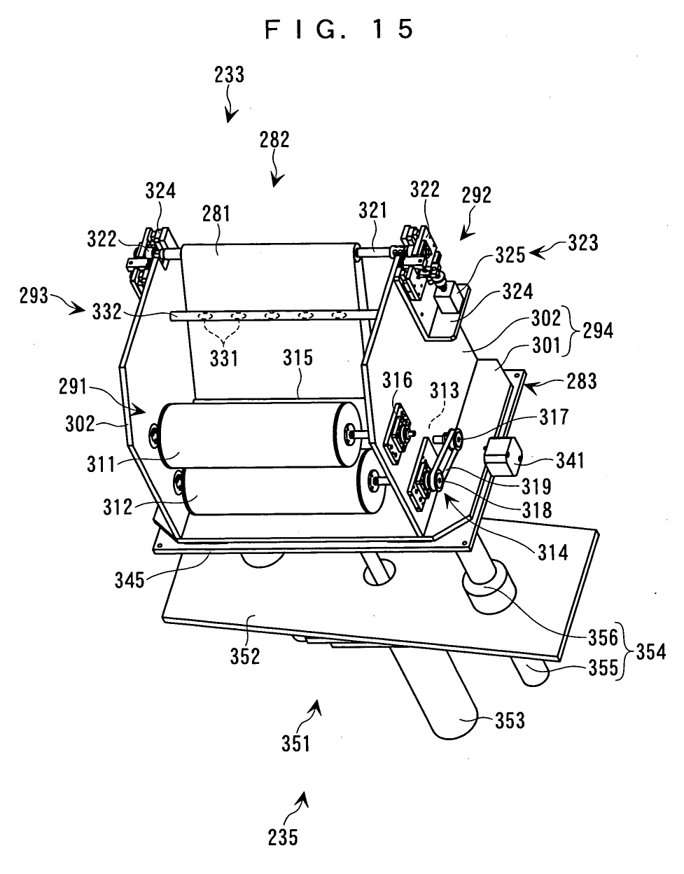

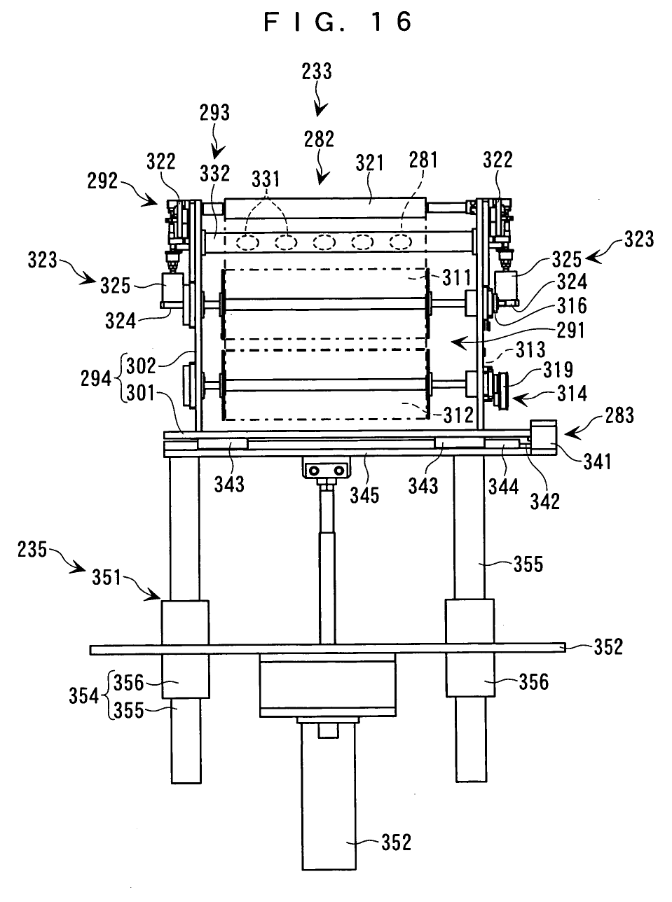

As shown in FIGS. 15 and 16, the wiping unit 233 includes a unit main body 282 serving as a major part thereof, and a transverse moving mechanism 283 slidably supporting the unit main body 282 in the X-axis direction. The unit main body 282 includes: a sheet-feeding unit 291 rolling out the rolled wiping sheet 281 while taking it up; a wipe-out unit 292 facing the function liquid droplet ejection heads 72 from below and wiping out the nozzle surfaces 87 with the wiping sheet 281; a cleaning liquid feeding unit 293 spreading cleaning liquid onto the delivered wiping sheet 281; and a wiping frame 294 supporting these components. The cleaning liquid fed to the wiping sheet 281 is a solvent of relatively volatile function liquid, hence effectively eliminating function liquid accreted on the nozzle surfaces 87 of the function liquid droplet ejection heads 72.

The wiping frame 294 includes a square wiping base 301 and a pair of side frames 302 disposed on the wiping base 301 in a standing manner so as to lie parallel to the X-axis direction. The sheet-feeding unit 291 is disposed on the left one of the pair of side frames 302 (close to the imaging area), and the wipe-out unit 292 is disposed above the right one (close to the suction unit 232). The cleaning liquid feeding unit 293 is supported by the side frames 302 so as to face the wiping sheet 281 delivered from the sheet-feeding unit 291 to the wipe-out unit 292.

As shown in FIGS. 15 and 16, the sheet-feeding unit 291 includes a delivery reel 311, shown in the upper part of the figure, having the rolled wiping sheet 281 mounted thereon, and delivering the wiping sheet 281 in its extending direction; a take-up reel 312 shown in the lower part of the figure and taking up the delivered wiping sheet 281; a take-up motor 313 rotating the take-up reel 312 for taking up the wiping sheet 281; a power transmission mechanism 314 transmitting the power of the take-up motor 313 to the take-up reel 312; and an intermediate roller 315 forwarding the wiping sheet 281 from the delivery reel 311 to the wipe-out unit 292.

The delivery reel 311 has a torque limiter 316 disposed at one of the shaft ends thereof lying outside the side frames 302 and rotating in a braking manner so as to resist the take-up motor 313, thereby providing a certain amount of tension to the delivered wiping sheet 281. The take-up motor 313 includes a geared motor and is fixed to one of the side frames 302. The power transmission mechanism 314 includes: a driving pulley 317 fixed to the output end of the take-up motor 313; an idle pulley 318 fixed to the shaft end of the take-up reel 312; and a timing belt 319 entrained between both pulleys 317 and 318. When the take-up motor 313 is driven, the timing belt 319 travels with the speed reduction train of the power transmission mechanism 314, and the power is thus transmitted to the take-up reel 312. The intermediate roller 315 has a speed detector 320 (see FIG. 18) at the shaft end thereof for detecting the forwarding speed of the wiping sheet 281. Each of the delivery reel 311, the take-up reel 312, and the intermediate roller 315 is rotatably supported by the side frames 302 at the bottom ends thereof such that the axis lines of these components lie parallel to the X-axis direction, i.e., the width direction of the wiping sheet 281. That is, the wiping sheet 281 is delivered in a direction perpendicular to the width direction (the X-axis direction) of the wiping sheet 281.

As shown in FIGS. 15 and 16, the wipe-out unit 292 has an axial length corresponding to the width of the wiping sheet 281 and includes: a wipe-out roller 321 making the wiping sheet 281 abut against the nozzle surface 87 of the function liquid droplet ejection head 72; a pair of bearing members 322 supporting both ends of the wipe-out roller 321; a roller-elevation mechanism 323 elevating the wipe-out roller 321 with the pair of bearing members 322; and a pair of L-shaped bearing frames 324 supporting these components and also fixed to the side frames 302. The wiping sheet 281 delivered from the delivery reel 311 passes the intermediate roller 315, goes around the wipe-out roller 321, and is then taken up by the take-up reel 312.

The wipe-out roller 321 is a free roller and rotatably supported by the pair of bearing members 322 such that its axial line coincides with the X-axis direction. That is, the wipe-out roller 321 is supported so as to be perpendicular to the nozzle rows of each function liquid droplet ejection head 72 mounted on the head unit 41, and the nozzle surfaces 87 is thus wiped out in the nozzle row direction (in the longitudinally wiping manner). In this case, the wipe-out roller 321 is preferably composed of flexible and elastic material such as rubber in order to prevent damage of the nozzle surface 87 of the function liquid droplet ejection head 72. The roller-elevation mechanism 323 includes a pair of roller-elevation cylinders 325 (air cylinders) fixed on the pair of side frames 302 so as to elevatably support the pair of bearing members 322. In other words, when the roller-elevation cylinders 325 are driven, the wipe-out roller 321 is elevated to a predetermined wipe-out position so as to abut against the nozzle surface 87 of the function liquid droplet ejection head 72 of the head unit 41 through the bearing members 322.

As shown in FIGS. 15 and 16, the cleaning liquid feeding unit 293 is made up of splay nozzles and includes: a plurality of cleaning liqiud nozzles 331 connected to a cleaning liqiud tank, which will be described later; and a nozzle-supporting member 332 stretching over the pair of side frames 302 and supporting the plurality of cleaning liqiud nozzles 331. The nozzle-supporting member 332 is disposed between the intermediate roller 315 and the wipe-out roller 321 and supported by the pair of side frames 302 at both ends thereof so as to lie parallel to the X-axis direction (the width direction of the wiping sheet 281). The plurality of cleaning liqiud nozzles 331 is arranged so as to face the wiping sheet 281 forwarded from the intermediate roller 315 to the wipe-out roller 321. In this case, preferably the plurality of cleaning liqiud nozzles 331 is evenly arranged in the X-axis direction such that cleaning liqiud is sprayed over the full width of the wiping sheet 281. Although the plurality of cleaning liqiud nozzles 331 is provided in this embodiment in order to supply cleaning liqiud over the full width of the wiping sheet 281, a single of the cleaning liqiud nozzle 331 is possibly provided by disposing a nozzle-moving mechanism moving it in the width direction of the wiping sheet 281.

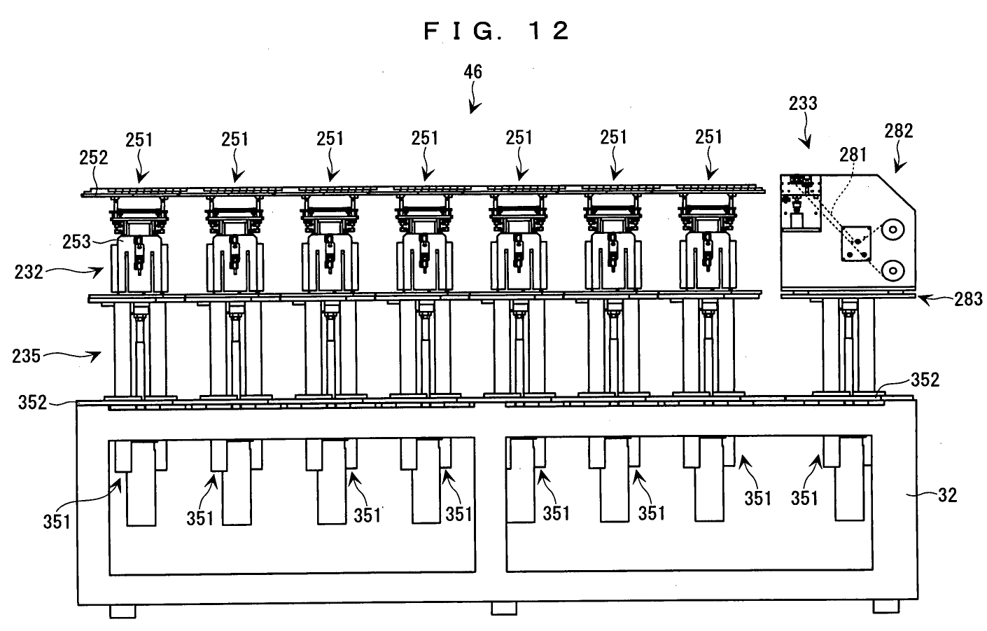

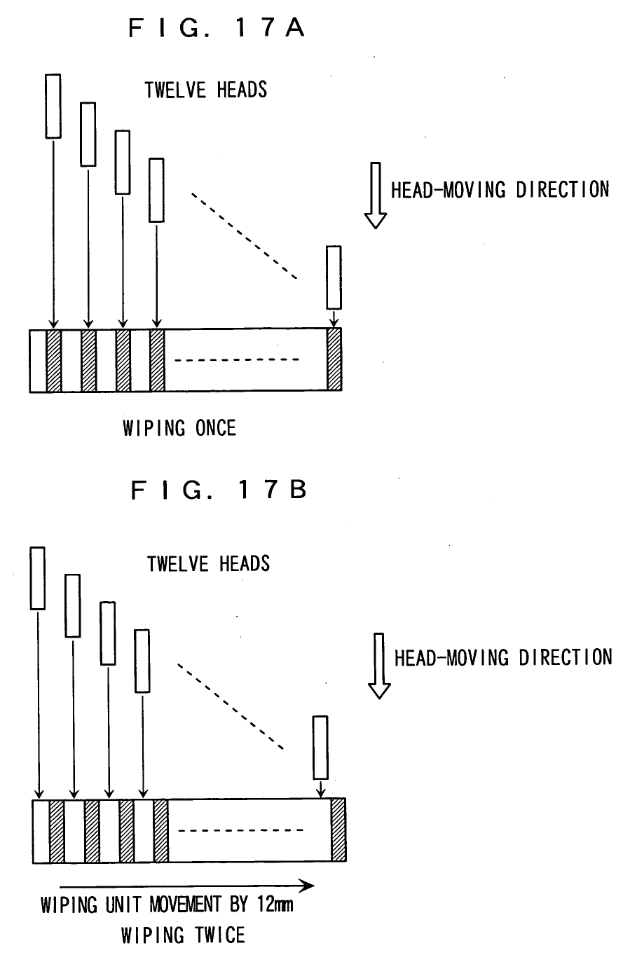

The transverse moving mechanism 283 is provided for moving the overall wiping sheet 281 through the unit main body 282 in the width direction thereof (the X-axis direction). As described above, the function liquid droplet ejection heads 72 are fixed to the head plate 73 with the respective holding members 74 and have a space between any two of the function liquid droplet ejection heads 72 being mutually adjacent to each other in the X-axis direction perpendicular to the nozzle rows (see FIG. 8). Accordingly, when the function liquid droplet ejection head 72 is wiped along an extending direction of the nozzle rows, stains are accreted on the wiping sheet 281 in a stripe pattern (FIG. 12A). That is, a part of the wiping sheet 281 corresponding to the spaces between the mutually adjacent function liquid droplet ejection heads 72 is not used for wiping and, instead, only another part of the same is used for wiping. In order to solve this problem, the transverse moving mechanism 283 is provided. When the wiping sheet 281 being subjected to a wiping operation once and accordingly tainted in a stripe pattern is transversely moved in the X-axis direction by the transverse moving mechanism 283, wiping parts of the wiping sheet 281 relative to the function liquid droplet ejection heads 72 are changed, whereby the part of the wiping sheet 281 corresponding to the spaces is effectively used (see FIG. 17B). Even when a mechanism is provided for moving the head unit 41 (the divided head units 71) in the X-axis direction in place of the transverse moving mechanism 283, and this mechanism is transversely moved relative to the wiping sheet 281, the same advantages can be achieved.

As shown in FIGS. 15 and 16, the transverse moving mechanism 283 includes: four transverse-moving sliders 343 in two sets slidably supporting the unit main body 282 in the X-axis direction; a transverse-moving ball screw 342 moving the four transverse-moving sliders 343 in two sets in the X-axis direction; a transverse-moving motor 341 rotating and counterrotating the transverse-moving ball screw 342; a pair of transverse-moving guides 344 extending in the X-axis direction and guiding the movement of the transverse-moving sliders 343; and a transverse-moving base 345 fixed to the foregoing unit-elevation mechanism 235 (serving also as a base plate 352) and supporting these components. When the transverse-moving motor 341 is driven, the transverse-moving sliders 343 are moved in the positive and negative X-axis direction with the transverse-moving ball screw 342, and the unit main body 282 is moved in the X-axis direction relative to the transverse-moving base 345.

In this embodiment, since the space between any two of the function liquid droplet ejection heads 72 being mutually adjacent to each other in the X-axis direction is approximately equal to the short side, perpendicular to the nozzle rows, of the function liquid droplet ejection head 72, the distance of the wiping sheet 281 transversely moved by the transverse moving mechanism 283 is set at the length of the short side of the function liquid droplet ejection head 72. That is, the wiping sheet 281 is moved by an amount of half the arrangement pitch of the function liquid droplet ejection heads 72 in the X-axis direction. Meanwhile, this value can be changed depending on kinds of function liquid and the wiping sheet 281, the arrangement pitch of the function liquid droplet ejection heads 72 in the X-axis direction, and so forth. In the transverse moving mechanism 283 according to this embodiment, the unit main body 282 is slid by motor drive. Alternatively, air drive achieved by rodless cylinders or the like is available in place of the motor drive.

A series of actions of the wiping unit 233 will be described. The cleaning liqiud feeding unit 293 is first driven such that cleaning liqiud is sprayed from the cleaning liqiud nozzles 331 so as to be fed to the wiping sheet 281, while the roller-elevation cylinders 325 are driven for elevating the wipe-out roller 321 to a position for wiping. Then, the take-up motor 313 is driven for forwarding the wiping sheet 281 containing the cleaning liqiud to the wipe-out roller 321. When the wiping sheet 281 reaches the wipe-out roller 321, driving of the take-up motor 313 and forwarding of the wiping sheet 281 are suspended. Subsequently, the head-moving means 43 is driven. With this, the head unit 41 moves to the maintenance area 52 in a state in which the nozzle surfaces 87 of the function liquid droplet ejection heads 72 mounted thereon abut (are pressed) against the wiping sheet 281 containing the cleaning liqiud. That is, the nozzle surfaces 87 of the function liquid droplet ejection heads 72 are slid against the wiping sheet 281 and are consequently wiped out by the wiping sheet 281.

Although details will be described later, since each divided head unit 71 is wiped in this embodiment, by arranging the seven divided head units 71 to face the wiping unit 233 one after another, the function liquid droplet ejection heads 72 mounted on the divided head unit 71 are continuously wiped. Hence, with this wiping unit 233, after a predetermined number of the divided head units 71 are wiped with the new wiping sheet 281, the transverse moving mechanism 283 is driven so as to drive the wiping sheet 281 in the X-axis direction. Then, after another predetermined number of the divided head units 71 are wiped, the take-up motor 313 is driven so as to forward the used wiping sheet 281.

The unit-elevation mechanism 235 will be described. The foregoing maintenance area 52 is not only used for maintenance of the function liquid droplet ejection heads 72, but also for maintenance of the suction units 232 and the wiping unit 233 and serves also as a workpieceing area for replacing the head plate 73 mounted on the carriage 75 with new one (hereinafter, this operation is referred to as head replacement). Hence, the unit-elevation mechanism 235 keeps the workpieceing area above the suction units 232 and the wiping unit 233 by lowering the suction units 232 and the wiping unit 233 from a predetermined maintenance position (access position) for performing maintenance of the function liquid droplet ejection heads 72 to a predetermined retracted position.

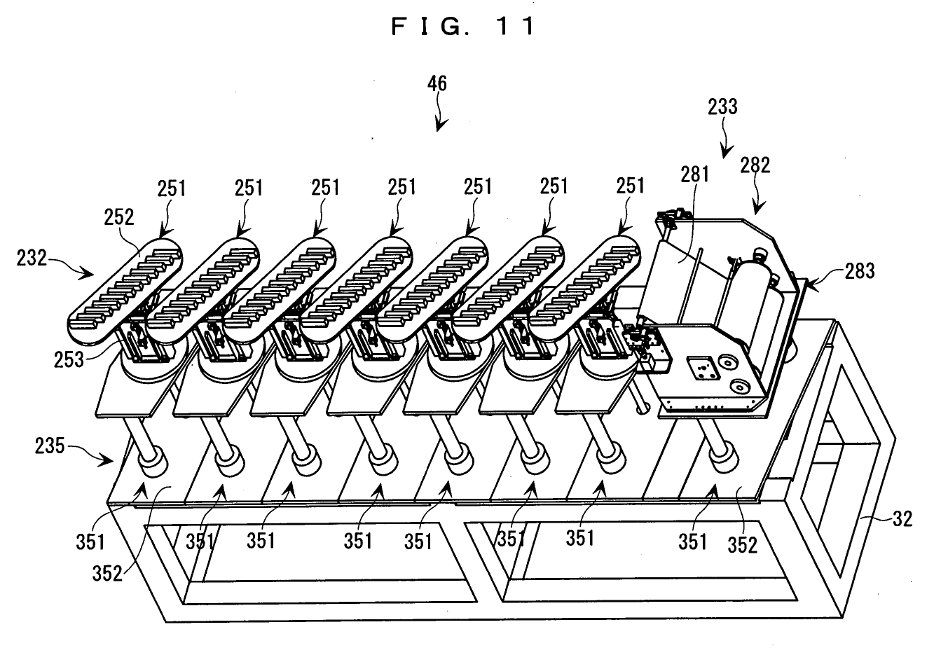

As shown in FIGS. 11 and 12, the unit-elevation mechanisms 235 include the eight elevation mechanisms 351, each supporting any one of the seven divided suction units 251 of the suction units 232 and the wiping unit 233, thereby independently elevating them between the maintenance position and the retracted position. As shown in FIGS. 13 to 16, the elevation mechanism 351 includes: the base plate 352 stretching over the foregoing angle frame 32; a unit-elevation cylinder 353 (an air cylinder) fixed to the base plate 352 and elevatably supporting the divided suction unit 251 or the wiping unit 233; and a pair of unit-elevation guides 354 guiding elevation movement of the divided suction units 251 or the wiping unit 233.

The unit-elevation cylinder 353 extends through the base plate 352, and the main body and the piston rod thereof are respectively fixed to the center of the lower surface of the base plate 352 and the divided suction unit 251 or the wiping unit 233. The elevation stroke of the unit-elevation cylinder 353 is set at 200 mm to 400 mm. The pair of unit-elevation guides 354 are made up of: a pair of guide shafts 355, each extending through the base plate 352 and the upper end thereof being fixed to the divided suction unit 251 or the wiping unit 233 guided thereby; and a pair of flange-equipped linear bushes 356 slidably engaging with the pair of guide shafts 355 and fixed to the base plate 352. The pair of guide shafts 355 is arranged symmetrically with respect to the unit-elevation cylinder 353 and stably guides elevation of the divided suction unit 251 or the wiping unit 233.

Normally, the unit-elevation mechanisms 235 support the suction units 232 and the wiping unit 233 at the maintenance position, and lower these components to the retracted position only when the suction unit 232, the wiping unit 233, or the head plate 73 is replaced with new one.

The fluid feeding/recovering means includes: a waste-fluid recovering system for recovering waste fluid from the flushing unit 231 of the maintenance means 46 into a waste-fluid tank; a function liquid recovering system for recovering function liquid into the reusing tank, sucked by the suction units 232 and that ejected to the suction units 232; a cleaning liqiud feeding system for feeding cleaning liqiud to the wiping unit 233; a cleaning liqiud tank (all not illustrated). The apparatus main body 22 has a tank cabinet disposed therein for accommodating the waste-fluid tank of the waste-fluid recovering system, the reusing tank of the function liquid recovering system, and the cleaning liqiud tank of the cleaning liqiud feeding system all together.

Referring now to FIG. 18, the main control system of the function liquid droplet ejection apparatus 3 will be described. As shown in the figure, the function liquid droplet ejection apparatus 3 includes an imaging section 361 including the head unit 41 (the function liquid droplet ejection heads 72) and the workpiece moving means 42; a head-moving section 362 including the head-moving means 43; a workpiece feeding/removing section 363 including the workpiece feeding-removing means 44; a maintenance section 364 including the maintenance means 46; a detection section 365 including a variety of sensors and performing a variety of detection; a drive section 366 driving the respective sections; and a control section 367 (the control unit 5) connected to the respective sections and controlling the entire function liquid droplet ejection apparatus 3.

The control section 367 includes: an interface 371 connecting a plurality of the foregoing means one another; a RAM 372 having a temporarily memorable area serving as a workpieceing area for control process; a ROM 373 having a variety of memory areas for storing control programs and control data; a hard disk 374 for storing, for example, imaging data used for performing imaging on the workpiece W, a variety of data of the plurality of means, and programs for processing the variety of data; a CPU 375 processing the variety of data according to the programs stored in the ROM 373, the hard disk 374 and the like; and a bus 376 connecting these components one another.

With this configuration, the control section 367 receives the variety of data of the plurality of means through the interface 371, processes them with CPU 375 according to the programs stored in the hard disk 374 (or sequentially read in a CD-ROM drive or the like, outputs the processed results to the variety means, and consequently controls the entire apparatus.

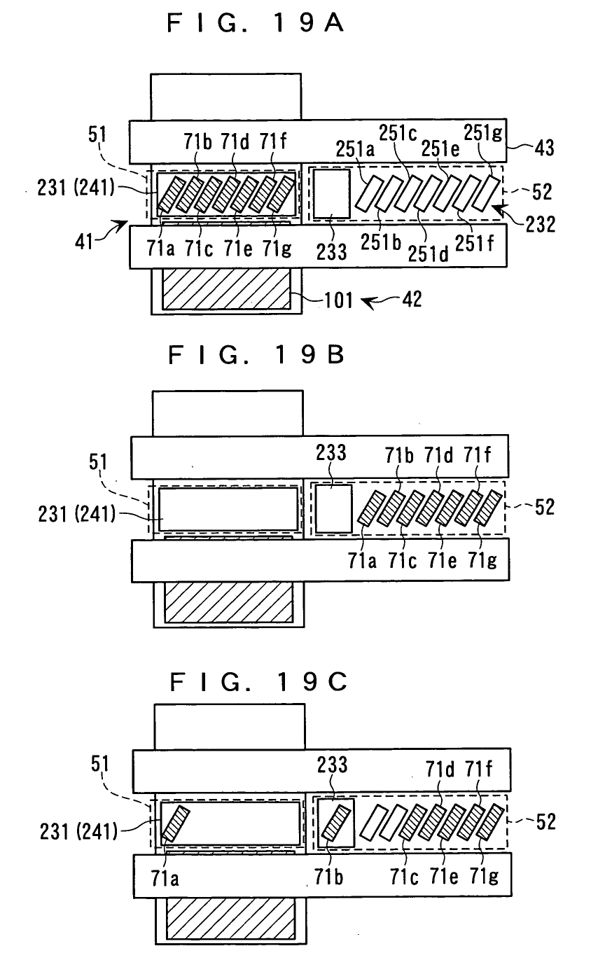

Referring to FIGS. 19 to 21, control of the function liquid droplet ejection apparatus 3 will be described, taking an example of performing maintenance of the head unit 41. Since the maintenance of the head unit 41 includes regular maintenance regularly performed at the time of replacement of the workpiece W and the head replacement in which the head plate 73 of the divided head unit 71 is replaced with new one in order to maintain and recover the functions of the function liquid droplet ejection heads 72 mounted on the function liquid droplet ejection apparatus 3, a control flow of the regular maintenance will be described and then a control flow of the head exchange will be described. For the sake of explanation, the seven divided head units 71 of the head unit 41 are denoted by the first to seventh divided head units 71a to 71g from the left in the figures. Likewise, the seven divided suction units 251 of the suction units 232 are denoted by the first to seventh divided suction unit 251a to 251g from the left in the figure.

In the regular maintenance, all function liquid droplet ejection heads 72 of the head unit 41 are sucked by the suction units 232, and are then wiped by the wiping unit 233. As shown in FIG. 19B, according to the control flow of the regular maintenance, the head-moving means 43 is first driven so as to move all seven divided head units 71 of the head unit 41 in the maintenance area 52 such that the seven divided head units 71 face the respective divided suction units 251. Then, the seven cap-elevation mechanisms 254 are driven so as to move the seven cap units 252 to the first position such that all function liquid droplet ejection heads 72 of the head unit 41 are closely attached by the corresponding caps 261. Subsequently, compressed air is fed to the ejector of all divided suction units 251 so as to suck all function liquid droplet ejection heads 72 of the head unit 41.

When suction of all function liquid droplet ejection heads 72 is finished, the cap-elevation mechanism 254 of the first divided suction unit 251a is driven so as to detach the caps 261 off the corresponding function liquid droplet ejection heads 72 of the first divided head unit 71a. Subsequently, the head-moving means 43 is driven so as to move the first divided head unit 71a toward the imaging area 51 and also, the wiping unit 233 is driven so as to wipe all function liquid droplet ejection heads 72 of the first divided head unit 71a. During this operation, the second to seventh divided head units 71b to 71g are on standby in a state in which the mounted function liquid droplet ejection heads 72 are sealed (capped) by the corresponding caps 261 of the second to seventh divided suction units 251b to 251g, thereby preventing the discharge nozzles 88 of the waiting function liquid droplet ejection heads 72 from drying and clogging.

When wiping of the first divided head unit 71a is nearly finished, the cap-elevation mechanism 254 of the second divided suction unit 251b is driven so as to detach the caps 261 of the waiting second divided head unit 71b off the corresponding function liquid droplet ejection heads 72. When wiping of the first divided head unit 71a is finished, drive of the head-moving means 43 is controlled so as to move the first divided head unit 71a to the imaging area 51, and also the transverse moving mechanism 283 of the wiping unit 233 is driven so as to move the wiping sheet 281 in the X-axis direction. Subsequently, the second divided head unit 71b is moved toward the imaging area 51 and is wiped (see FIG. 19C).

When wiping of the second divided head unit 71b is nearly finished, the cap-elevation mechanism 254 of the third divided suction unit 251c is driven so as to detach the caps 261 off the waiting third divided head unit 71c. When wiping of the second divided head unit 71b is finished, the drive of the head-moving means 43 is controlled so as to move the second divided head unit 71b to the imaging area 51, and also, the sheet-feeding unit 291 (the take-up motor 313) of the wiping unit 233 is driven so as to deliver and forward the wiping sheet 281 and to feed the new wiping sheet 281 containing cleaning liqiud to the wipe-out unit 292 (the wipe-out roller 321).

Then, the head-moving means 43 is driven so as to wipe the third divided head unit 71c. Subsequently, the waiting fourth to seventh divided head units 71d to 71g are subjected to the similar actions to the above ones, and the fourth to seventh divided head units 71d to 71g are wiped and moved to the imaging area 51 in that order.

At the same time, until the time when wiping of all divided head units 71 is finished, the function liquid droplet ejection heads 72 of the waiting divided head units 71 forwarded to the imaging area 51 are periodically driven for ejection at a predetermined interval and undergo a flushing operation. In this occasion, the set table 101 faces the workpiece carrying-in/out area 53 for performing the workpiece replacement, and the waiting divided head units 71 are flushed in the imaging area 51 while lying right above the flushing box 241.

In this embodiment, the divided head units 71 before undergoing a wiping operation are on standby while being capped and, alternatively, these head units may be on standby while being periodically flushed at a predetermined interval toward the caps 261 (while being subjected to an in-cap flushing operation). In this case, when the cap 261 are detached off the first divided head unit 71a, the cap-elevation mechanisms 254 of the second to seventh divided suction units 251b to 251g are driven so as to move the caps 261 of the second to seventh divided suction units 251b to 251g to the second position.

When a waiting time for wiping does not substantially affect ejecting features of the function liquid droplet ejection heads 72, for example, when function liquid having a very low volatile property is used, a capping operation during waiting and the in-cap flushing operation can be eliminated. In this case, since the capping and the in-cap flushing operations are not needed during waiting for a wiping operation, the suction units 232 may be made up of less than seven of the divided suction units 251. In particular, when the regular maintenance is not performed so often, reduction in the number of the divided suction units 251 affects little on the overall tact time, whereby the suction unit 232 can be made up of a single of the divided suction unit 251. On the contrary, when the regular maintenance is performed often, since a waiting time for the wiping operation affects the whole processing time, a plurality of the wiping unit 233 may be provided in order to reduce the above-described waiting time.

As shown in FIG. 19, in this embodiment, the divided head units 71 before undergoing the wiping operation do not move while waiting for the wiping operation and remain at the position where the divided head units 71 are sucked and, alternatively, every time when wiping of the previously wiped one of the divided head units 71 is finished, these head units 71 may be sequentially moved to the cap units 252 of the divided suction units 251 lying close to the imaging area 51 (close to the wiping unit 233).

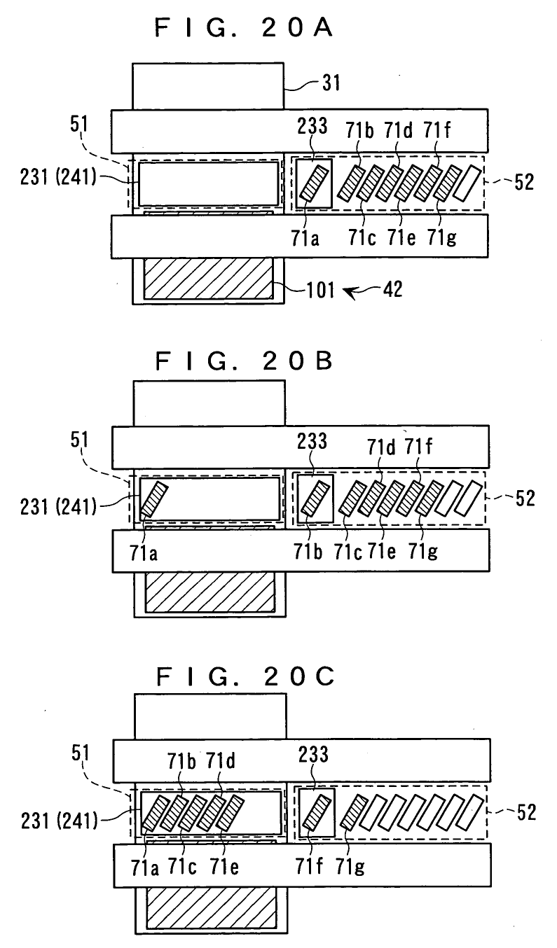

Referring to FIG. 20, the above-described operation will be described in detail. As shown in 20A, when the first divided head unit 71a facing the first divided suction unit 251a is moved to the wiping unit 233, the second to seventh divided head units 71b to 71g are moved to the first to sixth divided suction units 251a to 251f, respectively. Then, as shown in FIG. 20B, when wiping of the first divided head unit 71a is finished and the second divided head unit 71b facing the first divided suction unit 251a is moved to the wiping unit 233, the third to seventh divided head units 71c to 71g are moved the first to fifth divided suction units 251a to 251e, respectively. Also, in this case, the wiped divided head unit 71 is moved to the imaging area 51. By moving the waiting divided head units 71 to the divided suction units close to the wiping unit 233 in accordance with the movement of pervasively wiped divided head units 71 to the wiping unit 233, a time needed for wiping the head unit 41 (all divided head units 71) can be reduced as described above.

Further, in this embodiment, the wiping sheet 281 is transversely moved upon finishing of a single of the divided head unit 71 and, alternatively, timing of the transverse movement can be set according to the actual conditions (for example, the kind of function liquid). For example, it can be possible that the wiping sheet 281 is transversely moved after wiping two of the divided head units 71 and is delivered after wiping additional two of the divided head units 71. Also, for example, by disposing stain-detecting means (not illustrated) detecting the degree of stain of the wiping sheet 281 on the head plate 73 of each divided head unit 71 or the like, the wiping sheet 281 can be transversely moved according to the degree of stain of the wiping sheet 281. In this case, the stain-detecting means may be made up of a reflective photo sensor, a camera, and so forth.

Although all divided head units 71 making up the head unit 41 are sucked and wiped in the regular maintenance, those skilled in the art will appreciate that only any one of the divided head units 71 can be sucked and wiped. In this case, the head-moving means 43 is driven such that the divided head unit 71 to be sucked and to be wiped faces the first divided suction unit 251a.

The control flow of the head exchange will be described. In this embodiment, a space above the wiping unit 233, that is, above a part of the maintenance area 52 mostly close to the imaging area 51 serves as the head-exchanging area. The head-moving means 43 is first driven so as to move the divided head unit 71 to be subjected to the head exchange to the wiping unit 233. Then, the elevation mechanism 351 of the unit-elevation mechanisms 235 supporting the wiping unit 233 is driven so as to be moved to the foregoing retracted position. With this operation, a workpieceing space is generated above the wiping unit 233, whereby the head exchange is effectively performed. When the head exchange is finished, the foregoing elevation mechanisms 351 are driven again so as to elevate the wiping unit 233 and the first divided suction unit 251a to the maintenance position. In order to more effectively keep the workpieceing space, the first divided head unit 71a next to the wiping unit 233 is preferably moved to the retracted position.

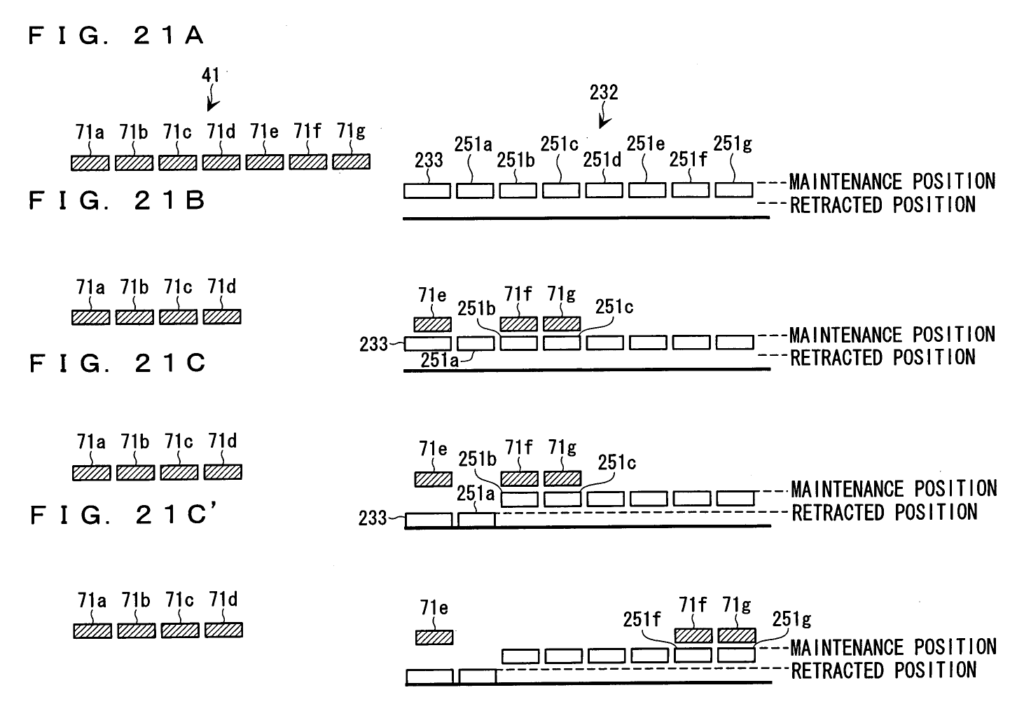

The head exchange flow will be described in detail, taking an example of exchange of the head plate 73 of the fifth divided head unit 71e. As shown in FIG. 21B, the head-moving means 43 is first driven so as to move the fifth to seventh divided head units 71e to 71g to the maintenance area 52 such that the fifth divided head unit 71e faces the wiping unit 233 while the sixth and seventh divided head units 71f and 71g face the second and third divided suction units 251b and 251c. Then, as shown in FIG. 21C, the elevation mechanisms 351 are driven so as to move the wiping unit 233 and the first divided suction unit 251a to the retracted position. Meanwhile, the moving positions of the sixth and seventh divided head units 71f and 71g are not limited to the above-described ones and, alternatively, these units may be moved so as to face the sixth and seventh divided suction units 251f and 251g, for example (see FIG. 21C′).

During an operation of the head exchange, in order to prevent drying and clogging of the function liquid droplet ejection heads 72 of the divided head units 71 which are not subjected to the operation, these divided head unit 71 are capped or periodically flushed. More particularly, the cap-elevation mechanisms 254 of the divided suction units 251 (i.e., the second and third divided suction units 251b and 251c) faced by the sixth and seventh divided head units 71f and 71g are driven so as to move the cap units 252 to the first or second position. Then, the first to fourth divided head units 71a to 71d face the flushing box 241 so as to be flushed while the sixth and seventh divided head units 71f and 71g are capped or subjected to the in-cap flushing.

When the head exchange operation is finished, the cap-elevation mechanisms 254 of the sixth and seventh divided suction units 251f and 251g faced by the sixth and seventh divided head units 71f and 71g are driven so as to lower the cap units 252 lying at the first or second position to the bottom position while the foregoing elevation mechanisms 351 are driven so as to elevate the wiping unit 233 and the first divided suction unit 251a to the maintenance position.

In this embodiment, a part of the divided head units 71 are left in the imaging area 51 during the operation of the head exchange and, alternatively; all divided head units 71 of the head unit 41 may be moved to the maintenance area 52. In this case, all seven divided head units 71 are arranged so as to face the corresponding divided suction units 251, and the six divided head units 71 excluding the divided head unit 71 (i.e., the fifth divided head unit 71e) to be subjected to the operation are then capped or subjected to the in-cap flushing.

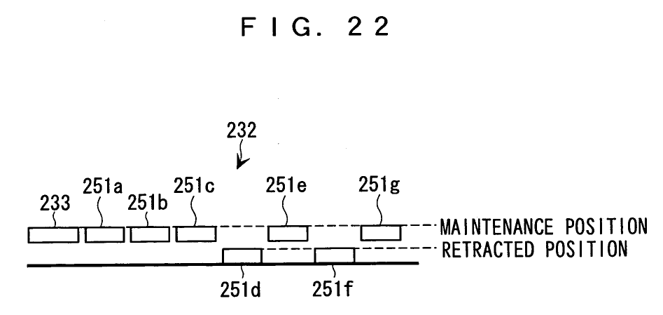

When each divided suction unit 251 of the suction units 232 or the wiping unit 233 is maintained, the unit to be maintained is not retracted, and another one of the divided suction units 251 or the wiping unit 233 next to the above-described unit is moved to the retracted position. Especially, when each of the first to sixth divided suction units 251a to 251f is maintained, both units next to the foregoing divided suction unit 251 to be maintained at both sides are driven to the retracted position (see FIG. 22).

As described above, with the control section 367, the overall control of the plurality of means is performed such that these means corporate with one another and a variety of processes is thus carried out.

Taking a color filter, a liquid crystal display device, an organic EL device, a (PDP) device, an electron-emission device such as an SED or an SED device, an active matrix substrate incorporated in these display devices, and the like as examples of electro-optical devices (flat panel displays) fabricated by incorporating the function liquid droplet ejection apparatus 3 according to this embodiment, structures and manufacturing methods thereof will be described. Meanwhile, the active matrix substrate has thin film transistors, source and data wires electrically connected to the thin film transistors formed therein.

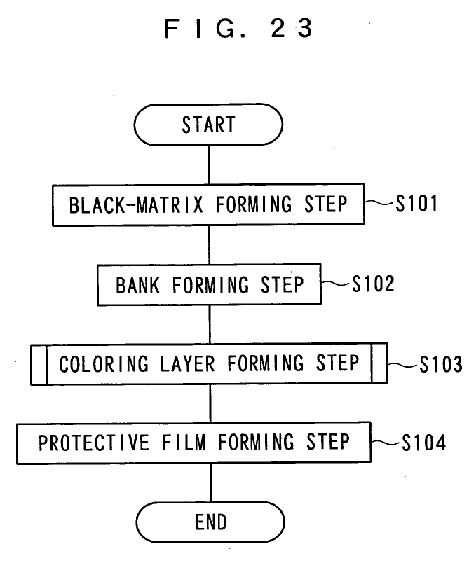

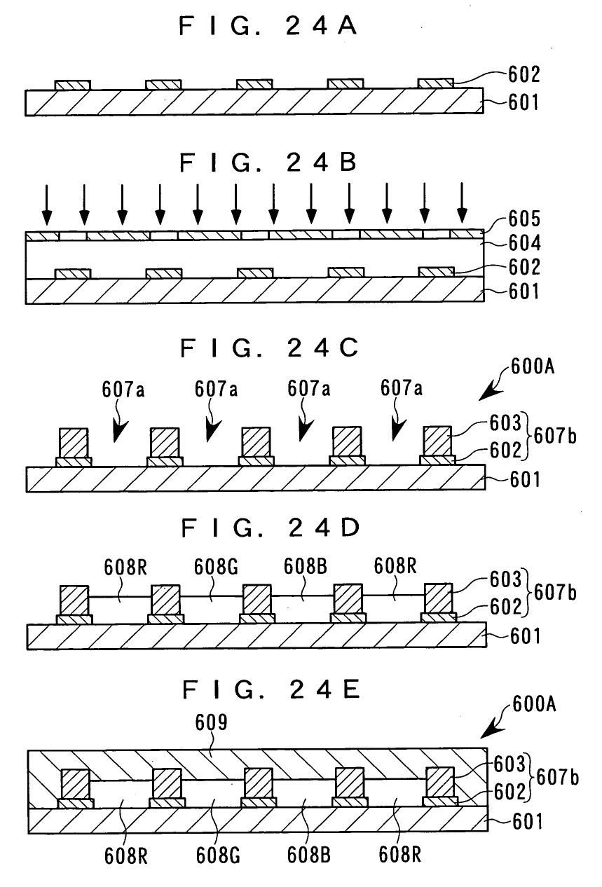

A method of manufacturing a color filter incorporated into a liquid crystal display device, an organic EL device, and the like will be described. FIG. 23 illustrates a flowchart of a manufacturing process of a color filter, and FIG. 24 is a schematic sectional view of a color filter 600 (a filter substrate 600A) according to this embodiment, showing it in order of its manufacturing steps.

In a black-matrix forming step S101, a black matrix 602 is formed on a substrate (W) 601 as shown in FIG. 24A. The black matrix 602 is composed of chromium metal, a laminate of chromium metal and chromic oxide, resin black, or the like. The black matrix 602 composed of a thin metal film is formed by spattering, comical vapor deposition, or the like. Also, the black matrix 602 composed of a resin thin film is formed by gravure printing, photo resist, thermal transfer, or the like.

Subsequently, in a bank forming step S102, a bank 603 is formed so as to overlie on the black matrix 602. In other words, as shown in FIG. 24B, a resist layer 604 composed of negative-type transparent photosensitive resin is formed so as to cover the substrate 601 and the black matrix 602. Then, the uncompleted color filter is exposed in a state in which its upper surface is covered by a mask film 605 formed in a matrix pattern.

Further, as shown in FIG. 24C, the resist layer 604 is patterned by etching an unexposed part of the resist layer 604, and the bank 603 is thus formed. Meanwhile, when the black matrix is composed of resin black, the black matrix serves also as the bank.

The bank 603 and the black matrix 602 below the bank 603 serve as a partition wall 607b partitioning each pixel area 607a and define a landing area of a function droplet when coloring layers (deposited film portions) 608R, 608G, and 608B are formed by the function liquid droplet ejection heads 72 in a coloring layer forming step which is performed later.

The filter substrate 600A is obtained upon undergoing the above-described black-matrix forming step and bank forming step.

In this embodiment, the bank 603 is composed of a resin material whose coated surface is lyophobic (hydrophobic) and also, the surface of the substrate (glass substrate) 601 is lyophilic (hydrophilic). Hence, landing accuracy of a droplet in each pixel area 607a encircled by the bank 603 (the partition wall 606b) is improved in the coloring layer forming step, which will be described later.

Then, as shown in FIG. 24D, in a coloring layer forming step S103, a function droplet is ejected by one of the function liquid droplet ejection heads 72 so as to be landed in each pixel area 607a encircled by the partition wall 606b. In this case, with the function liquid droplet ejection heads 72, three colors (R, G, and B) of function liquid (filter material) are introduced and their function droplets are ejected. An arranging pattern of the three colors (R, G, and B) can be a stripe pattern, a mosaic pattern, or a delta pattern.

Subsequently, the function liquid is fixed by drying (for example, by heating), and the coloring layers 608R, 608G, and 608B for the three color are thus formed. When the coloring layers 608R, 608G, and 608B are formed, the process moves to a protective film forming step S104. As shown in FIG. 24E, a protective film 609 is formed so as to cover the upper surfaces of the substrate 601, the partition wall 606b, and the coloring layers 608R, 608G, and 608B.

In other words, after coating fluid for the protective film is ejected across the entire surface of the substrate 601 having the coloring layers 608R, 608G, and 608B formed therein, the protective film 609 is dried and then formed.

Then, after the protective film 609 is formed, the color filter 600 is moved to the following film-depositing step in which a film composed of ITO (indium tin oxide) or the like and serving as transparent electrodes is deposited.

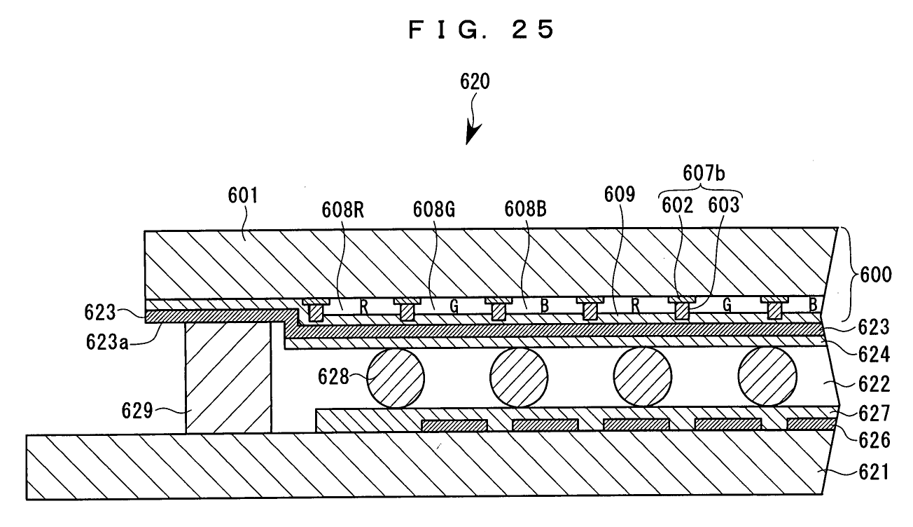

FIG. 25 is a sectional view of an essential part of a passive-matrix liquid crystal device (liquid crystal device) 620 as a first example liquid crystal display device having the foregoing color filter 600 incorporated therein, showing the general structure of the same. When accessory components such as a liquid-crystal driving IC, a backlight, a support member are placed on the liquid crystal device 620, a transmissive liquid crystal display device serving as a final product is achieved. Since the color filter 600 is identical to that shown in FIG. 24, the corresponding parts are denoted by the same reference numbers, and the descriptions thereof will be omitted.

The liquid crystal device 620 is generally made up of the color filter 600, a counter substrate 621 composed of a glass substrate or the like, and a liquid crystal layer 622 sandwiched by the above two components and composed of super twisted nematic (STN) liquid crystal composition, and the color filter 600 lies in the upper part of the figure (close to an observer).

Although not shown in the figure, polarizers are disposed on the respective outer surfaces (the respective surfaces opposite to the liquid crystal layer 622) of the counter substrate 621 and the color filter 600, and also, a backlight is disposed outside one of the polarizers lying close to the counter substrate 621.

On the protective film 609 of the color filter 600 (close to the liquid crystal layer), a plurality of strip-shaped first electrodes 623 extending long in the horizontal direction in FIG. 25 is formed at a predetermined interval, and a first alignment film 624 is formed so as to cover the surfaces of the first electrodes 623 opposite to the color filter 600.

At the same time, on the surface of the counter substrate 621 opposing the color filter 600, a plurality of strip-shaped second electrodes 626, each extending long in a direction perpendicular to the first electrodes 623 of the color filter 600 is formed at a predetermined interval, and a second alignment film 627 is formed so as to cover the surfaces of the second electrodes 626 close to the liquid crystal layer 622. The first and second electrodes 623 and 626 are composed of a transparent conductive material such as ITO.

Spacers 628 disposed in the liquid crystal layer 622 maintain the thickness (the cell gap) of the liquid crystal layer 622 constant. A sealant 629 prevents liquid crystal composition in the liquid crystal layer 622 from leaking outside. One end of each of the first electrodes 623 extends outside the sealant 629 so as to serve as a routing wire 623a.

Thus, intersections made by the first and second electrodes 623 and 626 serve as pixels, and the coloring layers 608R, 608G, and 608B of the color filter 600 are arranged so as to lie at the intersections serving as the corresponding pixels.

In the general manufacturing process, the first electrodes 623 are patterned and the first alignment film 624 is coated on the color filter 600 so as to prepare a portion of the color filter close to the color filter 600. In addition to this, the second electrodes 626 are patterned and the second alignment film 627 is coated on the counter substrate 621 so as to prepare a portion of the color filter close to the counter substrate 621. Then, the spacers 628 and the sealant 629 are built in the portion close to the counter substrate 621, and the above-described two portions are bonded to each other in this state. After liquid crystal constituting the liquid crystal layer 622 is filled in the liquid crystal layer 622 through an inlet of the sealant 629, the inlet is closed. Subsequently, both polarizers and the backlight are deposited.

With the function liquid droplet ejection apparatus 3 according to this embodiment, for example, a spacer material (function liquid) making up the foregoing cell gap can be applied, and also, before bonding the portion close to the color filter 600 to the portion close to the counter substrate 621, liquid crystal (function liquid) can be uniformly applied in the area enclosed by the sealant 629. Also, the foregoing sealant 629 can be printed with the function liquid droplet ejection heads 72. In addition, both first and second alignment films 624 and 627 can be also coated with the function liquid droplet ejection heads 72.

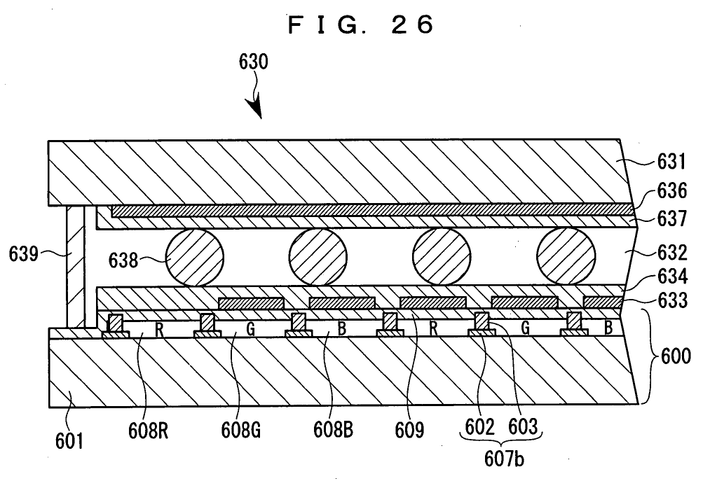

FIG. 26 is a sectional view of an essential part of a second example liquid crystal device 630 including the color filter 600 according to this embodiment, showing the general structure of the same.

The liquid crystal device 630 is greatly different from the liquid crystal device 620 in that the color filter 600 is disposed in the lower part of the figure (opposite to an observer).

The liquid crystal device 630 has a general structure in which a liquid crystal layer 632 composed of STN liquid crystal is sandwiched between the color filter 600 and a counter substrate 631 composed of a glass substrate or the like. Although not shown in the figure, polarizers and so forth are disposed on the outer surfaces of the counter substrate 631 and the color filter 600.

On the protective film 609 of the color filter 600 (close to the liquid crystal layer 632), a plurality of strip-shaped first electrodes 633 extending long in a direction perpendicular to the plane of the figure is formed at a predetermined interval, and a first alignment film 634 is formed so as to cover the surfaces of the first electrodes 633 close to the liquid crystal layer 632.

On the surface of the counter substrate 631 opposing the color filter 600, a plurality of strip-shaped second electrodes 636 extending perpendicular to the first electrodes 633 close to the color filter 600 is formed at a predetermined interval, and a second alignment film 637 is formed so as to cover the surfaces of the second electrodes 636 close to the liquid crystal layer 632.

In the liquid crystal layer 632, spacers 638 maintaining the thickness of the liquid crystal layer 632 constant and a sealant 639 preventing liquid crystal composition in the liquid crystal layer 632 from leaking outside are disposed.

In the same manner as the liquid crystal device 620, intersections made by the first electrodes 633 and the second electrodes 636 serve as pixels, and the coloring layers 608R, 608G, and 608B of the color filter 600 are arranged so as to lie at the intersections serving as the corresponding pixels.

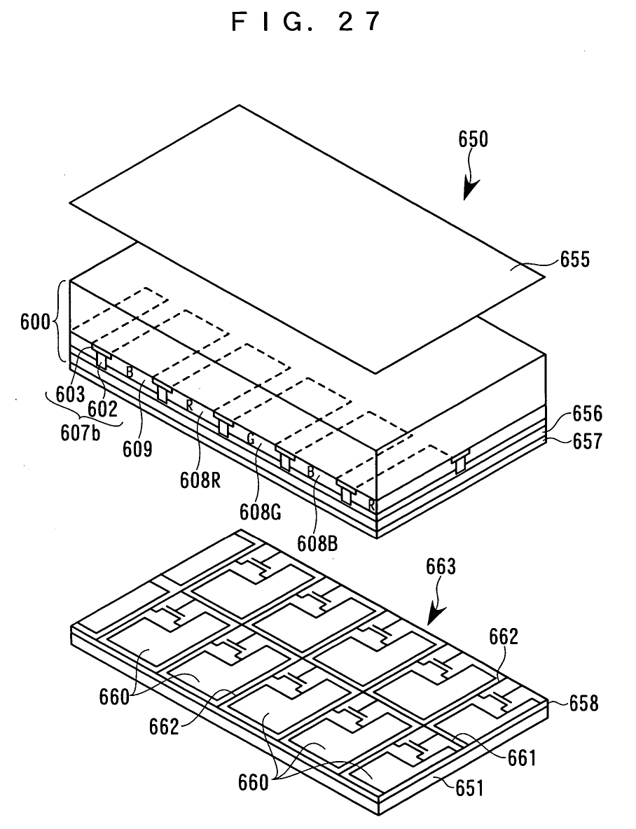

FIG. 27 is an exploded perspective view of a transmissive TFT (thin film transistor) liquid crystal device 650 as a third example liquid crystal device including the color filter 600 according to this invention, showing the general structure of the third example liquid crystal device.

The liquid crystal device 650 has a structure in which the color filter 600 lies in the upper part of the figure (close to an observer).

The liquid crystal device 650 is generally made up of: the color filter 600; a counter substrate 651 disposed so as to oppose the color filter 600; a liquid crystal layer (not illustrated) sandwiched between above two components; a polarizer 655 disposed on the upper surface of the color filter 600 (close to an observer); and a polarizer (not illustrated) disposed on the lower surface of the counter substrate 651.

On the surface of the protective film 609 (close to the counter substrate 651) of the color filter 600, a liquid-crystal driving electrode 656 is formed. The electrode 656 is composed of a transparent conductive material such as ITO, and serves as a full surface electrode covering the entire area where pixel electrodes 660, which will be described later, are formed. Also, an alignment film 657 is disposed so as to cover the surface of the electrode 656 opposite to the pixel electrodes 660.

The counter substrate 651 has an insulating layer 658 on the surface thereof opposing the color filter 600. The insulating layer 658 has scanning lines 661 and signal lines 662 formed thereon so as to be perpendicular to each other. The pixel electrodes 660 are formed in areas encircled by the scanning lines 661 and the signal lines 662. Although an alignment film is formed on the pixel electrodes 660 in an actual liquid crystal device, it is omitted in the figure.

Also, a thin film transistor 663 including a source electrode, a drain electrode, a semiconductor, and a gate electrode is built in a portion of each pixel electrode 660 encircled by a cut of the pixel electrode 660, each scanning line 661 and each signal line 662. By applying signals on the scanning lines 661 and the signal lines 662, the thin film transistor 663 is turned on or off so as to perform current-exciting control of the pixel electrodes 660.

Although each of the foregoing example liquid crystal devices 620, 630, and 650 is of a transmissive type, it can be of a reflective type or a transflective type by providing a reflective layer or a transflective layer.

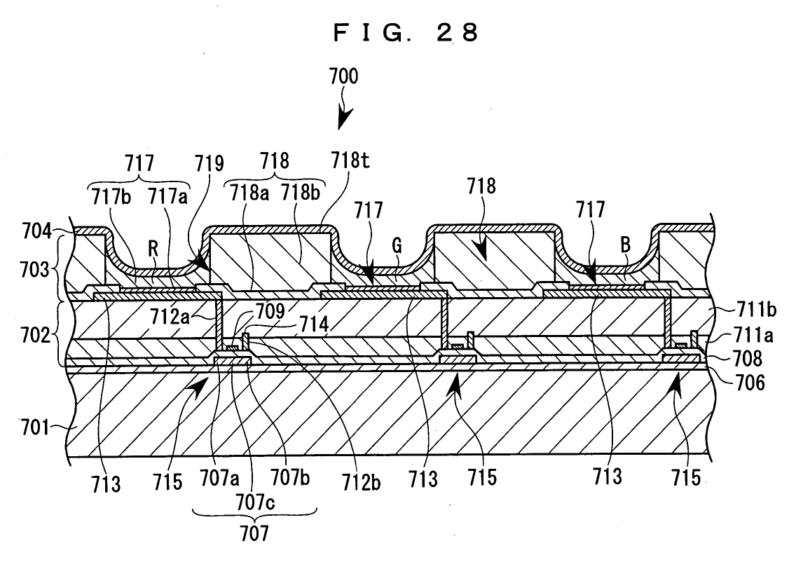

FIG. 28 is a sectional view of an essential part of a display area (hereinafter, simply referred to as a display device 700) of an organic EL device.

The display device 700 has a general structure in which a substrate (W) 701 has a circuit-element portion 702, an emitting-element portion 703, and a cathode 704 deposited thereon.

In the display device 700, light emitted from the emitting-element portion 703 toward the substrate 701 passes through the circuit-element portion 702 and the substrate 701 and is emitted toward an observer, while light emitted from the emitting-element portion 703 toward the opposite side to the substrate 701 is reflected from the cathode 704, then passes through the circuit-element portion 702 and the substrate 701, and is emitted toward the observer.

The circuit-element portion 702 and the substrate 701 have a substrate-protecting layer 706 formed therebetween, composed of a silicon oxide film. The substrate-protecting layer 706 has island-shaped semiconductor films 707 formed thereon (close to the emitting-element portion 703), composed of polycrystalline silicon. Each semiconductor film 707 has a source area 707a and a drain area 707b respectively formed in the left and right areas thereof by implanting highly concentrated cations, and the central part thereof having no cations implanted therein serves as a channel area 707c.

The circuit-element portion 702 has a transparent gate insulating film 708 formed therein, covering the substrate-protecting film 706 and the semiconductor films 707 and also has gate electrodes 709 composed of metal such as Al, Mo, Ta, Ti, or W, each formed at a position on the gate insulating film 708 corresponding to the channel area 707c of each semiconductor film 707. The gate electrode 709 and the gate insulating film 708 have transparent first and second interlayer insulating films 711a and 711b formed thereon. Also, the first and second interlayer insulating films 711a and 711b have contact holes 712a and 712b formed therethrough so as to communicate with the source area 707a and the drain area 707b of the semiconductor films 707, respectively.

The second interlayer insulating film 711b has transparent pixel electrodes 713 formed thereon in a predetermined pattern, composed of ITO or the like, and each pixel electrode 713 is connected to the source area 707a through the contact hole 712a.

The first interlayer insulating film 711a has a power line 714 disposed thereon and connected to the drain area 707b through the contact hole 712b.

As described above, the circuit-element portion 702 has driving thin-film transistors 715 formed therein, connected to the respective pixel electrodes 713.

The emitting-element portion 703 has a general structure in which each of a plurality of the pixel electrodes 713 has a function layer 717 deposited thereon, and each pixel electrode 713 and the function layer 717 have a bank portion 718 provided therebetween and partitioning the corresponding function layer 717.

The pixel electrode 713, the function layer 717, and the cathode 704 disposed on the function layer 717 make up emitting element. The pixel electrodes 713 are patterned in a rectangular shape in plan view, and any two of the pixel electrodes 713 have the bank portion 718 formed therebetween.

The bank portion 718 is made up of: an inorganic bank layer 718a (a first bank layer) composed of an inorganic material such as SiO, SiO₂, or TiO₂; and an organic bank layer 718b (second bank layer) deposited on the inorganic bank layer 718a composed of, for example, acrylic resin resist or polyimide resin resist, each having excellent thermal resistance and solvent resistance and having a trapezoidal cross-section. A part of the bank portion 718 overlies the periphery of each pixel electrode 713.

Any two mutually adjacent bank portions 718 have an opening 719 therebetween, formed such that it is widened upwards with respect to the pixel electrodes 713.

The function layer 717 us made up of a hole injection/transport layer 717a and an emitting layer 717b formed on the hole injection/transport layer 717a, both lying above the corresponding pixel electrode 713 and in the opening 719 in a deposited state. Meanwhile, another function layer having another function may be additionally formed adjacent to the emitting layer 717b. For example, an electron-transporting layer may be formed. The hole injection/transport layer 717a functions so as to transport holes from the pixel electrode 713 and to inject them into the emitting layer 717b. The hole injection/transport layer 717a is formed by ejecting a first composition (function liquid) containing a forming material. The forming material can be a known one.

The emitting layer 717b emits light of any one of colors red (R), green (G), and blue (B) and is formed by ejecting a second composition (function liquid) containing a forming material of the emitting layer (an emitting material). Known material insoluble to the hole injection/transport layer 717a is preferably used as a solvent (a nonpolar solvent) of the second composition. By using such a nonpolar solvent in the second composition of the emitting layer 717b, the emitting layer 717b can be formed without dissolving the hole injection/transport layer 717a again.

With this structure, since holes injected from the hole injection/transport layer 717a and electrons injected from the cathode 704 are coupled again in the emitting layer 717b, light is emitted from this layer.

The cathode 704 is formed so as to cover the entire surface of the emitting-element portion 703 and serves so as to pass electric current to the function layer 717 together with the pixel electrode 713 as a pair. The cathode 704 has a sealing member (not illustrated) disposed thereabove.

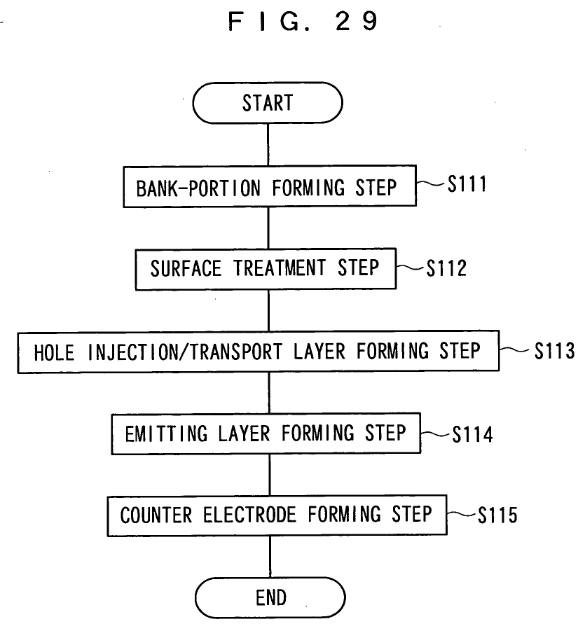

Referring now to FIGS. 29 to 37, the manufacturing process of the display device 700 will be described.

As shown in FIG. 29, the display device 700 is manufactured through a bank-potion forming step S111, a surface-finishing step S112, a forming step of the hole injection/transport layer S113, an emitting layer forming step S114, and a counter electrode forming step S115. The manufacturing process is not limited to that illustrated in the figure, and some steps may be eliminated from or added to the process.

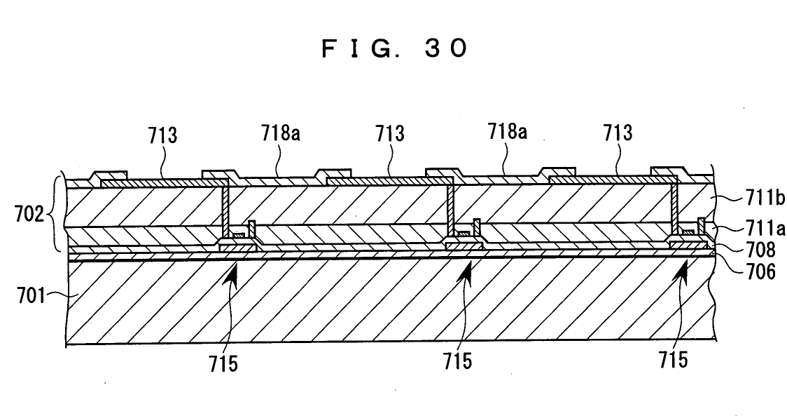

As shown in FIG. 30, in the bank-portion forming step S111, the inorganic bank layer 718a is formed on the second interlayer insulating film 711b such that an inorganic film is formed at its forming position and is then patterned by lithography or the like. In this occasion, a part of the inorganic bank layer 718a overlaps with the periphery of the corresponding pixel electrode 713.

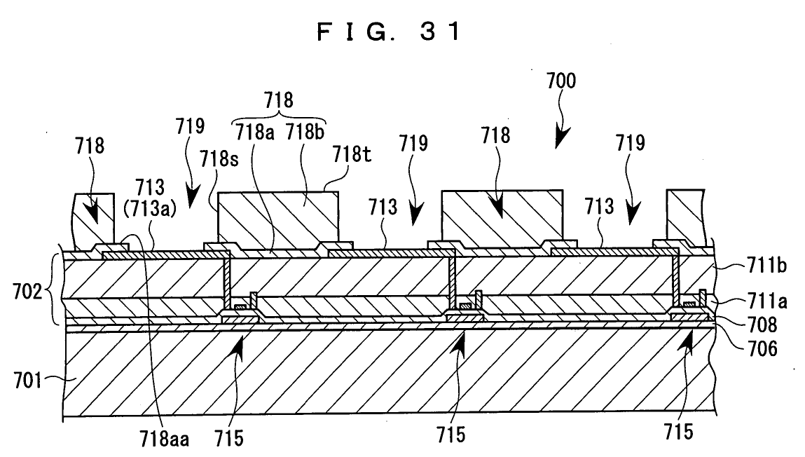

When the inorganic bank layer 718a is formed, as shown in FIG. 31, the organic bank layer 718b is formed on the inorganic bank layer 718a. The organic bank layer 718b is also formed by way of patterning by lithography or the like in the same manner as the inorganic bank layer 718a.

The bank portion 718 is formed as described above. In accordance with this formation, any two of mutually adjacent bank portions 718 have the opening 719 formed therebetween, opening upwards with respect to the pixel electrodes 713. This opening 719 defines a pixel area.

In the surface-finishing step S112, lyophilic and fluid-repellent treatments are performed. The lyophilic treatment is applied on a first deposited portion 718aa of the inorganic bank layer 718a and an electrode surface 713a of the pixel electrode 713, and the surfaces of these areas are finished so as to be lyophilic by plasma treatment using oxygen as a process gas, for example. The plasma treatment serves also so as to clean ITO making up the pixel electrodes 713.

Also, the fluid-repellent treatment is applied on wall surfaces 718s and an upper surface 718t of the organic bank layer 718b, and these surfaces are finished so as to be fluid-repellent by plasma treatment using methane tetra-fluoride as a process gas, for example.

By carrying out the surface-finishing step, when the function layer 717 is formed with the function liquid droplet ejection head 72, a function liquid droplet can be more reliably landed in the corresponding pixel area, and also, the function liquid droplet landed in the pixel area is prevented from leaking from the opening 719.

Thus, a display-device substrate 700A is obtained by carrying out the above-described steps. The display-device substrate 700A is placed on the set table 101 of the function liquid droplet ejection apparatus 3 shown in FIG. 1, and the forming step S113 of the hole injection/transport layer and the emitting layer forming step S114 which will be described below are carried out.

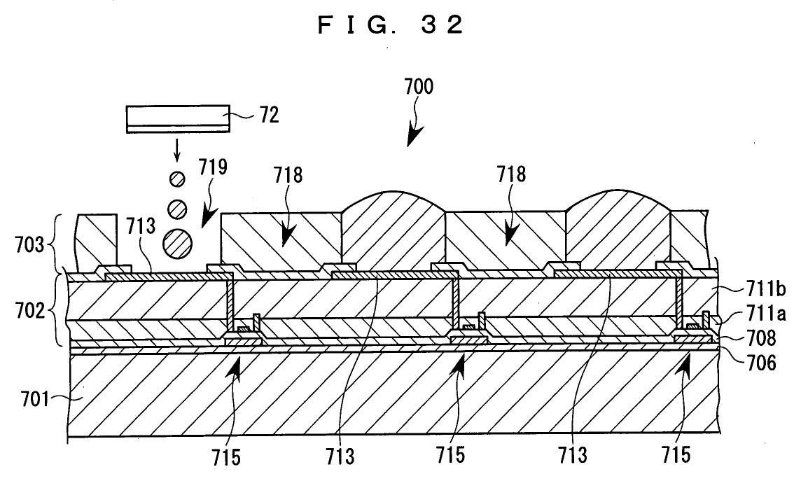

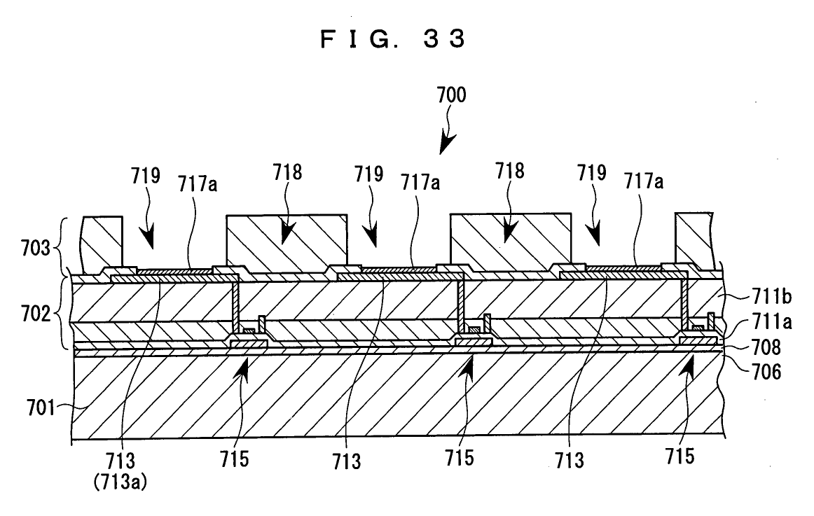

As shown in FIG. 32, in the forming step S113 of the hole injection/transport layer, the function liquid droplet ejection head 72 ejects the first composition containing the forming material of the hole injection/transport layer in the corresponding opening 719 serving as a pixel area. Then, a polar solvent contained in the first composition is vaporized by drying and heating so as to form the hole injection/transport layer 717a on the pixel electrode 713 (the electrode surface 713a) 713 as shown in FIG. 33.

The emitting layer forming step S114 will be described. In the emitting layer forming step, as described above, in order to prevent the hole injection/transport layer 717a from being dissolved again, a nonpolar solvent insoluble to the hole injection/transport layer 717a is used as a second composition upon forming the emitting layer.

On the other hand, since the hole injection/transport layer 717a has low affinity to a nonpolar solvent, even when the second composition containing a nonpolar solvent is ejected on the hole injection/transport layer 717a, there is a risk that the hole injection/transport layer 717a and the emitting layer 717b are not closely attached with each other, or the emitting layer 717b is not uniformly coated.

Hence, in order to improve the affinity of the surface the hole injection/transport layer 717a to the nonpolar solvent and the emitting layer forming material, a surface finishing (a surface-improving treatment) is preferably carried out prior to formation of the emitting layer. The surface finishing is carried out by applying a surface-improving material identical or similar to the second composition used upon formation of the emitting layer on the hole injection/transport layer 717a and then by drying it.

With such treatments, since the surface of the hole injection/transport layer 717a has affinity to a nonpolar solvent, the second composition containing the emitting layer forming material can be uniformly applied on the hole injection/transport layer 717a in the following steps.

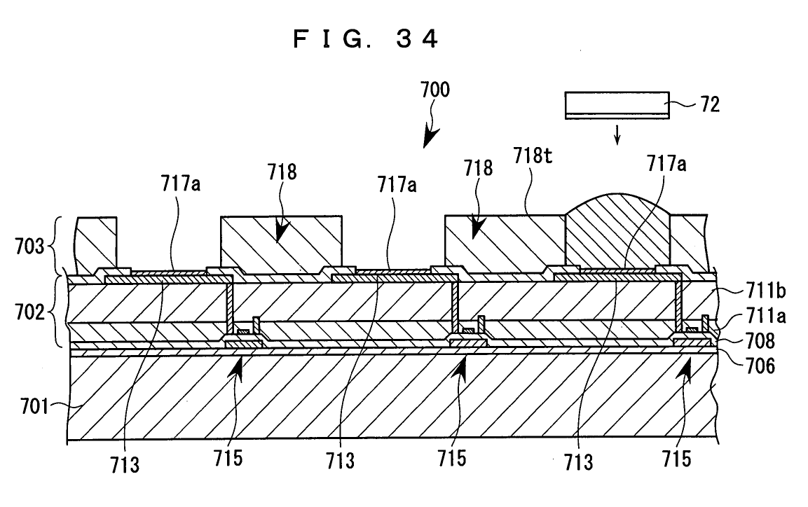

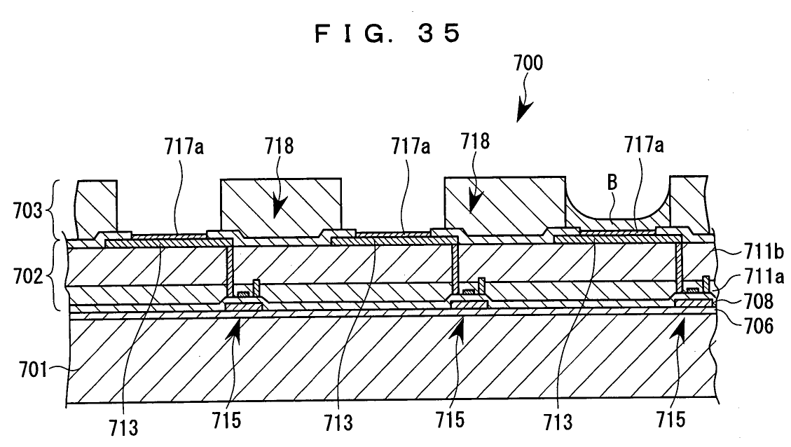

Then, as shown in FIG. 34, a predetermined amount of the second composition containing the emitting layer forming material corresponding to any one of colors (blue (B) in the example illustration in FIG. 35) is implanted in the pixel area (the opening 719) as a function liquid droplet. The second composition implanted in the pixel spreads over the hole injection/transport layer 717a and is filled in the opening 719. Meanwhile, in case that the second composition is landed outside the pixel area and on the upper surface 718t of the bank portion 718, since the fluid-repellent treatment has been previously applied to the upper surface 718t as described above, the second composition is likely to roll in the opening 719.

Subsequently, by carrying out a drying step and so forth, when the ejected second composition is dried, and nonpolar solvent contained in the second composition is evaporated, the emitting layer 717b is formed on the hole injection/transport layer 717a as shown in FIG. 35. In the figure, the emitting layer 717b corresponding to the blue color (B) is formed.

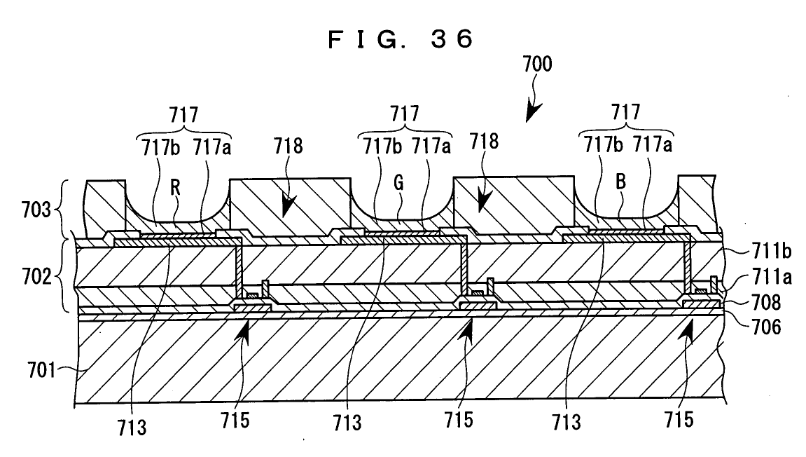

Likewise, with the function liquid droplet ejection head 72, as shown in FIG. 36, when the steps similar to those of the emitting layer 717b corresponding the above-described blue color (B) are sequentially carried out, the emitting layers 717b corresponding to the other red (R) and (G) colors are formed. Meanwhile, the emitting layers 717b is not limited to being formed in the foregoing example order and can be formed in any order. For example, the order can be determined depending on emitting-layer forming materials. Also, an arranging pattern of the three colors (R, G, and B) can be a stripe pattern, a mosaic pattern, or a delta pattern, or the like.

The function layer 717 is formed on the pixel electrodes 713, that is, the hole injection/transport layer 717a and the emitting layer 717b are formed on the same in the manner as described above. Then, the process moves to the counter electrode forming step S115.

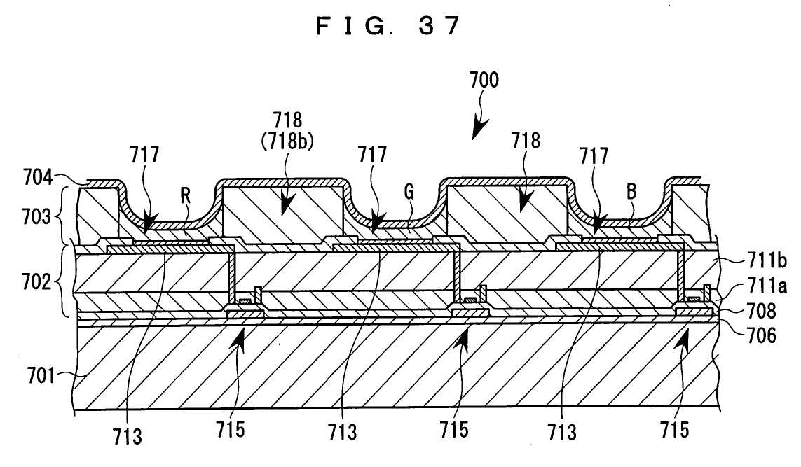

In the counter electrode forming step S115, as shown in FIG. 37, the cathode 704 (the counter electrode) is formed on the entire surfaces of the emitting layer 717b and the organic bank layer 718b, by vapor deposition, sputtering, chemical vapor deposition (CVD), or the like. According to this embodiment, the cathode 704 is a laminate of a calcium layer and an aluminum layer, for example.

A protective layer composed of SiO₂, SiN, or the like is disposed above the cathode 704 if needed so as to serve as an antioxidant against Al and Ag film serving as electrodes.

After the cathode 704 is formed as described above, when other treatments such as a sealing treatment for sealing a portion of the display device 700 above of the cathode 704 with sealing member and a wiring treatment are carried out, the display device 700 is obtained.

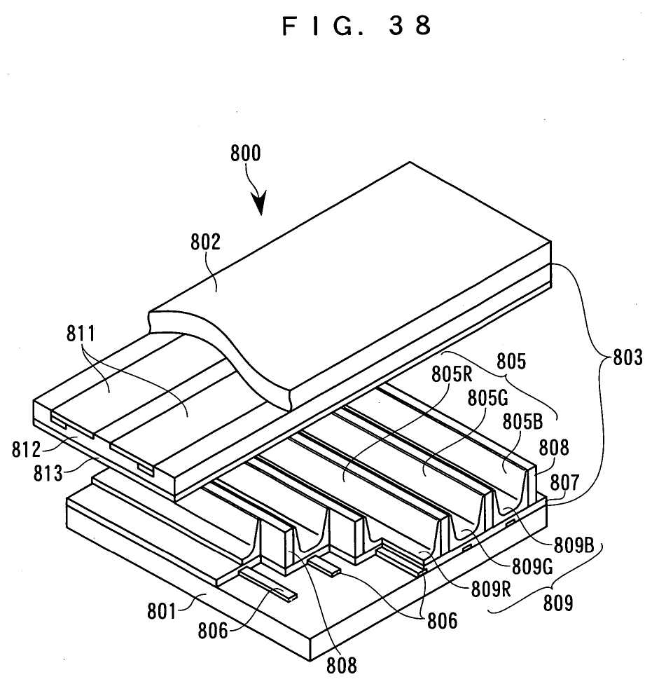

FIG. 38 is an exploded perspective view of an essential part of a plasma display panel (PDP) device (hereinafter, simply referred to as a display device 800), wherein a part of the display device 800 is cut away.

The display device 800 includes mutually opposing first and second substrates 801 and 802, and a discharge display portion 803 sandwiched between these substrates. The discharge display portion 803 includes a plurality of discharge chambers 805. Of the plurality of discharge chambers 805, a set of red, green, and blue discharge chambers 805R, 805G, and 805B is arranged so as to serve as a single pixel.

The first substrate 801 has address electrodes 806 formed on the upper surface thereof in a stripe pattern at a predetermined interval, and a dielectric layer 807 is formed so as to cover the upper surfaces of the address electrodes 806 and the first substrate 801. The dielectric layer 807 has barriers 808 disposed thereon in a standing manner, each lying between two of the address electrodes 806 and extending along the corresponding address electrode 806. The barriers 808 include those extending along the address electrodes 806 as shown in the figure and those (not illustrated) extending perpendicular to the address electrodes 806.

Thus, areas partitioned by the barriers 808 serve as the discharge chambers 805.

The discharge chambers 805 have respective fluorescent members 809 disposed therein. Each fluorescent substance 809 emits fluorescent light of any one of colors red (R), green (G), and blue (B), and the red, green, and blue discharge chambers 805R, 805G, and 805B respectively have red, green, and blue fluorescent members 809R, 809G, and 809B disposed at the bottoms thereof.

The second substrate 802 has a plurality of display electrodes 811 disposed on the lower surface thereof, as shown in the figure, so as to extend in a direction perpendicular to the address electrodes 806, in a stripe pattern at a predetermined interval, and a dielectric layer 812 and a protective film 813 composed of MgO or the like are formed so as to cover these electrodes.

The first and second substrates 801 and 802 are bonded to each other such that the address electrodes 806 and the display electrodes 811 are perpendicular to each other. The address electrodes 806 and the display electrodes 811 are connected to respective alternating power sources (not illustrated).

By energizing each of the electrodes 806 and 811, the fluorescent members 809 emits excitation light in the discharge display portion 803 so as to offer color display.

According to this embodiment, the address electrodes 806, the display electrodes 811, and the fluorescent members 809 can be formed with the function liquid droplet ejection apparatus 3 shown in FIG. 1. A forming step of the address electrodes 806 of the first substrate 801 will be described by way of example.

In this case, the following step is carried out in a state in which the first substrate 801 is placed on the set table 101 of the function liquid droplet ejection apparatus 3.

Firstly, a function liquid droplet of liquid material (function liquid) containing a containing conductive-film wiring forming material is landed in an address-electrode forming area with the function liquid droplet ejection heads 72. This liquid material contains conductive fine particles composed of metal or the like, dispersed in disperse media so as to serve as a conductive-film wiring forming material. This conductive particle can be a metal fine particle containing, for example, gold, silver, copper, palladium, nickel, a conductive polymer particle, or the like.

When refilling of the liquid material in all address-electrode forming areas to be refilled is finished, by drying the ejected liquid material and by evaporating dispersion media contained in the liquid material, the address electrodes 806 are formed.

Although the address electrodes 806 are formed by way of example in the above description, the display electrodes 811 and the fluorescent members 809 can be also formed by undergoing the foregoing respective steps.

When the display electrodes 811 are formed, in the same manner as the address electrodes 806, a function liquid droplet of a liquid material (function liquid) containing a conductive-film wiring forming material is landed in a display-electrode forming area.

When the fluorescent members 809 are formed, function liquid droplets of liquid materials (function liquid) containing fluorescent materials corresponding to the respective colors (R, G, and B) are ejected by the function liquid droplet ejection heads 72 and landed in the discharge chambers 805 corresponding to the respective colors.

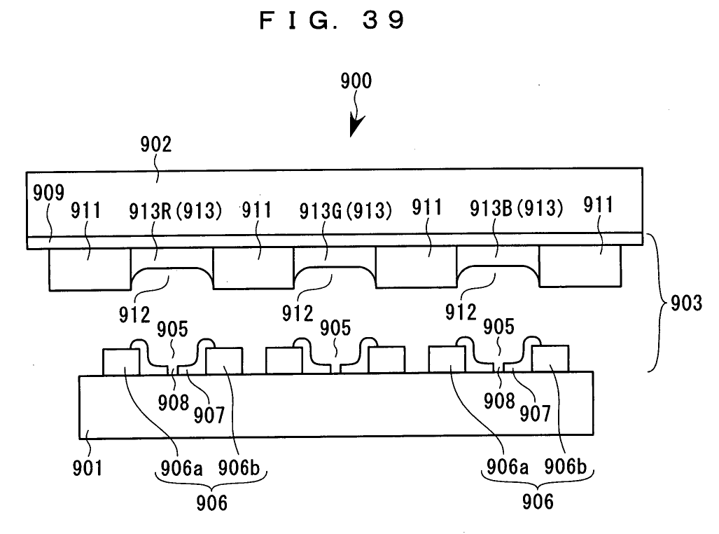

FIG. 39 is a sectional view of an essential part of an electron-emission device (also called an FED device or an SED, hereinafter simply referred to as a display device 900).

The display device 900 generally includes mutually opposing first and second substrates 901 and 902 and a field-emission display portion 903 formed between these substrates. The field-emission display portion 903 is made up of a plurality of electron-emission portions 905 arranged in a matrix pattern.

The first substrate 901 has first element electrodes 906a and second element electrodes 906b formed on the upper surface thereof, making up cathode electrodes 906, so as to be perpendicular to each other. Also, a conductive film 907 having a gap 908 formed therein is formed in a portion partitioned by each first element electrode 906a and each second element electrode 906b. That is, the first element electrodes 906a, the second element electrodes 906b, and the conductive films 907 make up the plurality of electron-emission portions 905. Each conductive film 907 is composed of palladium oxide (PdO) or the like, and the gap 908 is formed, for example, by foaming after the conductive film 907 is formed.

The second substrate 902 has anode electrodes 909 on the lower surface thereof so as to oppose the cathode electrodes 906. The anode electrodes 909 have bank portions 911 formed in a latticed pattern on the lower surface thereof. Downwardly-directed openings 912 encircled by the bank portions 911 have fluorescent members 913 disposed therein so as to correspond to the respective electron-emission portions 905. Each of the fluorescent members 913 emits fluorescent light of any one of colors red (R), green (G), and blue (B), and red, green, and blue fluorescent members 913R, 913G, and 913B are disposed in the above-described predetermined pattern in the respective openings 912.

Then, the first and second substrates 901 and 902 formed as described above are bonded to each other having a fine gap therebetween. In the display device 900, when an electron emitted from the first or second electrode 906a or 906b making up the cathode hits upon the fluorescent member 913 formed on the under surface of the anode electrode 909 serving as an anode, through the conductive film 907 (the gap 908), the fluorescent member 913 emits excitation light, thereby offering color display.

Also in this case, in the same manner as in the other embodiments, the first and second element electrodes 906a and 906b, the conductive film 907, and the anode electrodes 909 can be formed with the function liquid droplet ejection apparatus 3, and the fluorescent members 913R, 913G, and 913B corresponding to the respective colors can be also formed with the function liquid droplet ejection apparatus 3.

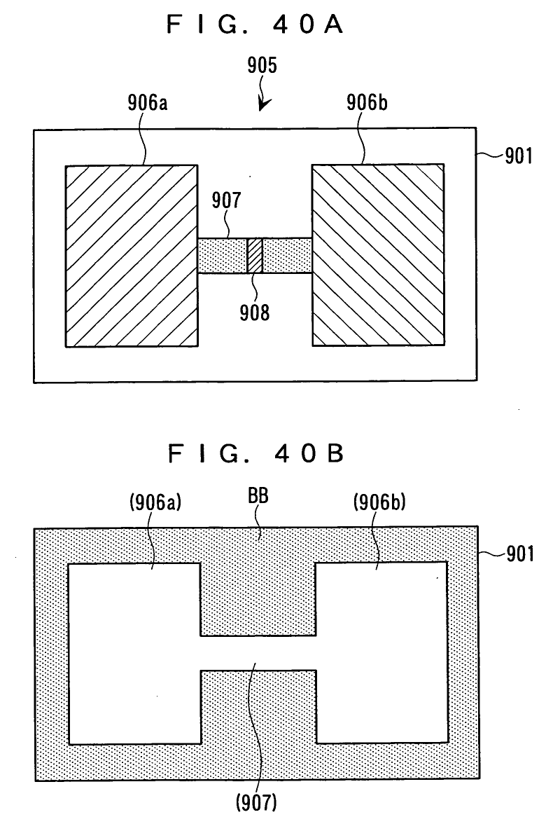

Since the first and second element electrodes 906a and 906b, and the conductive film 907 have respective two dimensional shapes shown in FIG. 40A, when these components are formed, a bank portion BB is formed by lithography while portions in which the first and second element electrodes 906a and 906b and the conductive film 907 are to be formed are previously left in an unprocessed state as shown in FIG. 40B. Subsequently, the first and second element electrodes 906a and 906b are formed by an inkjet method with the function liquid droplet ejection apparatus 3 in depressions formed by the bank portion, the solvent is dried so as to complete these components; and the conductive film 907 is then formed by an inkjet method with the function liquid droplet ejection apparatus 3. When the conductive film 907 is completed, the bank portion BB is removed by ashing, and the foregoing forming treatment is then carried out. In the same manner as in the organic EL device, the first and second substrates 901 and 902, and the bank portions 911 and BB and are preferably subjected to the lyophilic treatment and the fluid-repellent treatment, respectively.

Another electro-optical device can be a forming device of a metal wire line, a lens, a resist, a light-dispersing member, or the like. Application of the foregoing function liquid droplet ejection apparatus 3 allows a variety of electro-optical devices to be effectively manufactured.

1. A liquid droplet ejection apparatus comprising:
imaging means for performing imaging on a workpiece facing an imaging area by ejecting function liquid onto the workpiece while moving a function liquid droplet ejection head having function liquid introduced therein relative to the workpiece; and
maintenance means juxtaposed to the imaging means, for performing maintenance of the function liquid droplet ejection head facing the maintenance area,
said imaging means comprising: an an X-axis table for mounting thereon the workpiece and for moving the workpiece in the X-axis direction which serves as a main scanning direction; a plurality of carriage units each having mounted on a carriage the function liquid droplet ejection head; and a Y-axis table for moving the plurality of carriage units between the imaging area and the maintenance area,
wherein the Y-axis table is capable of moving the plurality of carriage units independently.

2. The apparatus according to claim 1, wherein a single imaging line corresponding to the width of the imaging area is made up of all discharge nozzles of a plurality of the function liquid droplet ejection heads mounted on the plurality of carriage units.

3. The apparatus according to claim 1, wherein a drive source of the Y-axis table is a linear motor.

4. The apparatus according to claim 1, wherein each of the carriage units comprises:
a carriage supported by a slider of the Y-axis table; and
a head unit which is detachably held by the carriage and which has the function liquid droplet ejection head and a head plate having mounted thereon the function liquid droplet ejection head,
wherein the maintenance area serves also as an exchange area for attaching or detaching each head unit to or from the corresponding carriage.

5. The apparatus according to claim 4, wherein each of the head plates has a plurality of the function liquid droplet ejection heads mounted thereon,
wherein the plurality of the function liquid droplet ejection heads are disposed in a predetermined arrangement pattern such that all discharge nozzles thereof make up a partial imaging line so as to serve as a part of the imaging line, and
wherein the arrangement pattern is achieved by a group of the liquid droplet ejection heads displaced in a stepwise manner and also in a single row in the X-axis and Y-axis directions, respectively.

6. The apparatus according to claim 4, wherein each of the head plates has the plurality of the function liquid droplet ejection heads mounted thereon,
wherein the plurality of the function liquid droplet ejection heads are disposed in a predetermined arrangement pattern such that all discharge nozzles thereof make up a partial imaging line so as to serve as a part of the imaging line, and
wherein the arrangement pattern is achieved by a group of the liquid droplet ejection heads displaced in a stepwise manner, respectively in the X-axis and Y-axis directions and also in a plurality of rows in the Y-axis direction.

7. The apparatus according to claim 1, wherein each of the carriage units has a function liquid tank mounted thereon for feeding function liquid to the function liquid droplet ejection head.

8. The apparatus according to claim 1, wherein the maintenance means comprises a suction unit for sucking function liquid from each of the ejection nozzles of the function liquid droplet ejection head, and a wiping unit for wiping the nozzle surface of the sucked function liquid droplet ejection head with a wiping sheet.

9. A method of manufacturing an electro-optical device, comprising forming a deposited film on the workpiece with function liquid droplets with the function liquid droplet ejection apparatus according to claim 1.

10. An electro-optical device having formed a deposited film on the workpiece with function liquid droplets with the function liquid droplet ejection apparatus according to claim 1.

11. An electronic apparatus having mounted thereon an electro-optical device manufactured by the method according to claim 9.

12. An electronic apparatus having mounted thereon the electro-optical device according to claim 10.
